(19) United States
(12) Patent Application Publication
(10) Pub. No.: US 2024/0222284 A1
(43) Pub. Date: Jul. 4, 2024

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Bongju Cho, Suwon-si (KR); Jingu Kim, Suwon-si (KR); Yieok Kwon, Suwon-si (KR); Wooyoung Kim, Suwon-si (KR); Gongje Lee, Suwon-si (KR); Sangkyu Lee, Suwon-si (KR)

(21) Appl. No.: 18/228,278

(22) Filed: Jul. 31, 2023

(30) Foreign Application Priority Data
Dec. 29, 2022 (KR) 10-2022-0188120

(51) Int. Cl. H01L 23/538; H01L 23/00; H01L 23/10

(52) U.S. Cl. CPC H01L 23/5386; H01L 23/10; H01L 24/05; H01L 24/13; H01L 24/46; H01L 24/73; H01L 2224/02331; H01L 2224/05024; H01L 2224/13008; H01L 2224/46

(57) ABSTRACT

Semiconductor package includes lower redistribution layer providing first redistribution wirings and having first region and second region surrounding the first region, semiconductor chip disposed on the first region and electrically connected to the first redistribution wirings, sealing member covering the semiconductor chip on the lower redistribution layer, plurality of vertical conductive structures penetrating the sealing member on the second region and electrically connected to the first redistribution wirings, upper redistribution layer disposed on the sealing member and having second redistribution wirings electrically connected to the plurality of vertical conductive structures and plurality of bonding pads. The vertical conductive structures are bonded to the bonding pad and extend vertically from the plurality of bonding pads. The vertical conductive structure includes first to third conductive pillar portions sequentially stacked. The first conductive pillar portion has first length and the third conductive pillar portion has third length greater than the first length.

### PRIORITY STATEMENT

This application claims priority under 35 U.S.C. § 119 to Korean Patent Application No. 10-2022-0188120, filed on Dec. 29, 2022 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a fan out semiconductor package and a method of manufacturing the same.

### 2. Description of the Related Art

In manufacturing a fan out package, a sealing member may be formed on a lower redistribution layer to cover a semiconductor chip and Cu posts may be formed to penetrate the sealing member. In order to form the Cu posts, a photosensitive insulating material such as a photoresist pattern may be formed on the lower redistribution layer, and a conductive material may fill openings of the photoresist pattern. When an aspect ratio of the opening is large, there are problems in that residues and undercuts may occur in subsequent processes.

### SUMMARY

Example embodiments provide a semiconductor package including vertical conductive structures having a large aspect ratio.

Example embodiments provide a method of manufacturing the semiconductor package.

According to example embodiments, a semiconductor package includes a lower redistribution layer having a first region and a second region surrounding the first region, wherein the lower redistribution layer includes a plurality of first redistribution wirings, a semiconductor chip disposed on the first region of the lower redistribution layer and electrically connected to the plurality of first redistribution wirings, a sealing member disposed on the lower redistribution layer and covering the semiconductor chip, a plurality of vertical conductive structures disposed on the second region of the lower redistribution layer and penetrating the sealing member, wherein the plurality of vertical conductive structures are electrically connected to the plurality of first redistribution wirings, an upper redistribution layer disposed on the sealing member, wherein the upper redistribution layer includes a plurality of second redistribution wirings that are electrically connected to the plurality of vertical conductive structures, and a plurality of bonding pads. The plurality of vertical conductive structures are connected to the plurality of bonding pads and extend from the plurality of bonding pads in a vertical direction that is perpendicular to an upper surface of the lower redistribution layer. Each of the plurality of vertical conductive structures includes a first conductive pillar portion, a second conductive pillar portion, and a third conductive pillar portion that are sequentially stacked on a corresponding bonding pad of the bonding pads. The first conductive pillar portion has a first length in the vertical direction and the third conductive pillar portion has a third length in the vertical direction greater than the first length. A diameter of an upper surface of the first conductive pillar portion that is opposite to a lower surface thereof bonded to the corresponding bonding pad is greater than a diameter of a lower surface of the third conductive pillar portion that is adjacent to the first conductive pillar portion.

According to example embodiments, a semiconductor package includes a lower redistribution layer having a plurality of first redistribution wirings, a semiconductor chip disposed on the lower redistribution layer, wherein the semiconductor chip includes a plurality of chip pads at a first surface of the semiconductor chip, and wherein the first surface of the semiconductor chip is adjacent to the lower redistribution layer, a sealing member disposed on the lower redistribution layer and covering the semiconductor chip, a plurality of vertical conductive structures penetrating the sealing member and electrically connected to the plurality of first redistribution wirings, an upper redistribution layer disposed on the sealing member and having a plurality of second redistribution wirings that are electrically connected to the plurality of vertical conductive structures, and a plurality of bonding pads respectively connected to one end portions of the plurality of vertical conductive structures. Each of the plurality of vertical conductive structures includes a first conductive pillar portion, a second conductive pillar portion, and a third conductive pillar portion that are sequentially stacked on a corresponding bonding pad of the plurality of bonding pads. The first conductive pillar portion has a first length, the second conductive pillar portion has a second length less than the first length, and the third conductive pillar portion has a third length greater than the first length. The first conductive pillar portion has a first tapered shape and the third conductive pillar portion has a third tapered shape different from the first tapered shape.

According to example embodiments, a semiconductor package includes a lower redistribution layer having a first region and a second region surrounding the first region, wherein the lower redistribution layer includes a plurality of first redistribution wirings, a semiconductor chip disposed on the first region of the lower redistribution layer, wherein the semiconductor chip includes a plurality of chip pads at a first surface of the semiconductor chip, and wherein the first surface of the semiconductor chip is adjacent to the lower redistribution layer, a sealing member disposed on the lower redistribution layer and covering the semiconductor chip, a plurality of vertical conductive structures penetrating the sealing member, wherein the plurality of vertical conductive structures are disposed on the second region of the lower redistribution layer and are electrically connected to the plurality of first redistribution wirings, an upper redistribution layer disposed on the sealing member and having a plurality of second redistribution wirings electrically connected to the plurality of vertical conductive structures, and a plurality of bonding pads respectively bonded to one end portions of the plurality of vertical conductive structures. Each of the plurality of vertical conductive structures includes a first conductive pillar portion, a second conductive pillar portion and a third conductive pillar portion that are sequentially stacked on a corresponding bonding of the plurality of bonding pads. The first conductive pillar portion has a first aspect ratio and the third conductive pillar portion has a second aspect ratio greater than the first aspect ratio. A diameter of an upper surface of the first conductive pillar portion that is opposite to a lower surface thereof connected to the bonding pad is greater than a diameter of a lower surface of the third conductive pillar portion that is adjacent to the first conductive pillar portion.

According to example embodiments, in a method of manufacturing a semiconductor package, a lower redistribution layer having a first redistribution wirings and having a first region and a second region surrounding the first region is formed. A plurality of vertical conductive structures are formed on the second region of the lower redistribution layer to be electrically connected to the first redistribution wirings. A semiconductor chip is mounted on the first region of the lower redistribution layer and electrically connected to the first redistribution wirings. A sealing member may be formed on the lower redistribution layer to cover the semiconductor chip and the plurality of vertical conductive structures. An upper redistribution layer having second redistribution wirings is formed on the sealing member to be electrically connected to the plurality of vertical conductive structures. In order to form the plurality of vertical conductive structures, a first photosensitive insulating layer, a light blocking layer and a second photosensitive insulating layer are sequentially formed on an upper surface of the lower redistribution layer, third openings are formed to penetrate the second photosensitive insulating layer to expose portions of the light blocking layer, the portions of the light blocking layer exposed by the third openings are etched to form second openings that expose the first photosensitive insulating layer, first openings are formed to penetrate the first photosensitive insulating layer to expose bonding pads on uppermost first redistribution wirings among the first redistribution wirings, and the first to third openings are filled up with a conductive material to form the plurality of vertical conductive structures electrically connected to the bonding pads.

According to example embodiments, a semiconductor package as a fan-out wafer level package may include a lower redistribution layer, a semiconductor chip mounted on the lower redistribution layer, a sealing member covering at least a portion of the semiconductor chip on an upper surface of the lower redistribution layer, a plurality of vertical conductive structures penetrating the sealing member, an upper redistribution layer disposed on an upper surface of the sealing member and a plurality of bonding pads respectively bonded to end portions of the vertical conductive structures.

Each of the vertical conductive structures may include first to third conductive pillar portions sequentially stacked on each of the bonding pads and formed integrally with each other. The first conductive pillar portion may have a first aspect ratio, and the third conductive pillar portion may have a second aspect ratio greater than the first aspect ratio.

A first photoresist layer of positive type and a second photoresist layer of negative type may be sequentially formed, openings may be formed in the first and second photoresist layer, and then, the openings may be filled up with a conductive material to form the vertical conductive structure. Accordingly, the vertical conductive structures as Cu posts having a large aspect ratio may be formed without generating residue under the photoresist layer.

### BRIEF DESCRIPTION OF THE DRAWINGS

FIG. 1 is a cross-sectional view illustrating a semiconductor package in accordance with example embodiments.

FIG. 2 is an enlarged cross-sectional view illustrating portion ‘A’ in FIG. 1.

FIGS. 3 to 16 are views illustrating a method of manufacturing a semiconductor package in accordance with example embodiments.

FIG. 17 is a cross-sectional view illustrating a semiconductor package in accordance with example embodiments.

FIG. 18 is a cross-sectional view illustrating a semiconductor package in accordance with example embodiments.

FIG. 19 is an enlarged cross-sectional view illustrating portion ‘F’ in FIG. 18.

FIGS. 20 to 32 are views illustrating a method of manufacturing a semiconductor package in accordance with example embodiments.

FIG. 33 is a cross-sectional view illustrating a semiconductor package in accordance with example embodiments.

FIGS. 34 to 38 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings.

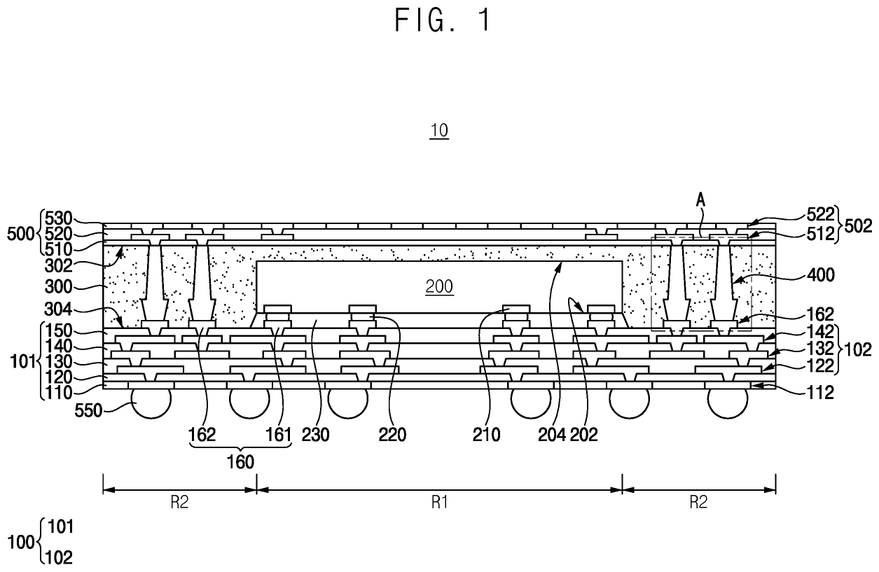

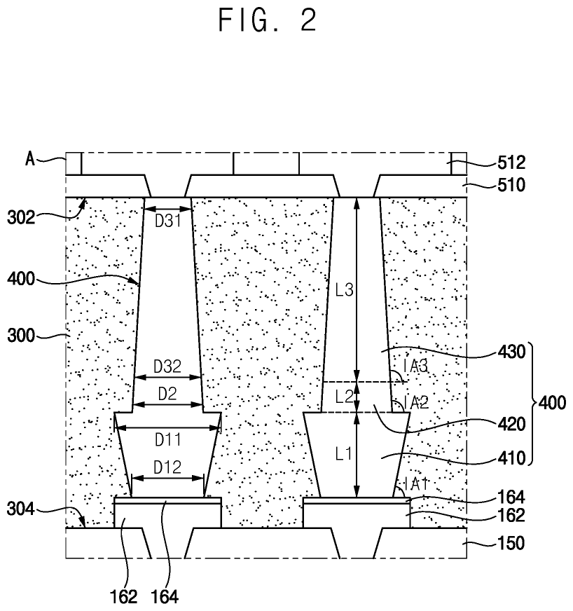

FIG. 1 is a cross-sectional view illustrating a semiconductor package in accordance with example embodiments. FIG. 2 is an enlarged cross-sectional view illustrating portion ‘A’ in FIG. 1.

Referring to FIGS. 1 and 2, a fan-out wafer level package 10 may include a lower redistribution layer 100, a semiconductor chip 200 disposed on the lower redistribution layer 100, a sealing member 300 covering at least a portion of the semiconductor chip 200 on an upper surface of the lower redistribution layer 100, an upper redistribution layer 500 disposed on an upper surface 302 (i.e., a first surface) of the sealing member 300, and a plurality of vertical conductive structures 400 penetrating the sealing member 300 and electrically connecting the lower redistribution layer 100 and the upper redistribution layer 500 with each other. In addition, the fan-out wafer level package 10 may further include external connection members 550 disposed on an outer surface of the lower redistribution layer 100.

In example embodiments, the fan-out wafer level package 10 may be a fan-out package in which the lower redistribution layer 100 extends to the sealing member 300 covering an outer surface of the semiconductor chip 200. A wafer-level redistribution wiring process may be performed to form the lower redistribution layer 100. Additionally, the fan-out wafer level package 10 may be provided as a unit package on which a second package is stacked.

In addition, the fan-out wafer level package 10 may be provided as a system in package (SIP). For example, one or more semiconductor chips may be disposed on the lower redistribution layer 100. The semiconductor chips may include a logic chip providing a logic circuit and/or a memory chip. The logic chip may be a controller to control memory chips. The memory chip may include various types of memory circuits such as dynamic random access memory (DRAM), static random access memory (SRAM), flash memory, Phase-change random access memory (PRAM), Resistive random access memory (ReRAM), Ferroelectric random access memory (FeRAM) and Magnetoresistive random access memory (MRAM).

In example embodiments, the lower redistribution layer 100 may have first redistribution insulating layers 101 and first redistribution wirings 102. The semiconductor chip 200 may be disposed on the lower redistribution layer 100 to be electrically connected to the first redistribution wirings 102. The lower redistribution layer 100 may be disposed on a front surface 202 (i.e., a first surface) of the semiconductor chip 200 to serve as a front redistribution layer. Thus, the lower redistribution layer 100 may be a front redistribution layer (FRDL) of a fan-out package.

The first redistribution insulating layers 101 of the lower redistribution layer 100 may include a plurality of first to fifth lower insulating layers 110, 120, 130, 140 and 150. The first redistribution wirings 102 may be disposed in the first to fifth lower insulating layers 110, 120, 130, 140 and 150. The first redistribution wirings 102 may include first to third lower redistribution wirings 122, 132 and 142.

The first to fifth lower insulating layers may include or may be formed of a polymer or a dielectric layer. For example, the first to fifth lower insulating layers may include or may be formed of a photosensitive insulating layer such as photo imageable dielectric (PID). The first to fifth lower insulating layers may be formed by a vapor deposition process or a spin coating process. The first redistribution wirings may include or may be formed of aluminum (Al), copper (Cu), tin (Sn), nickel (Ni), gold (Au), platinum (Pt), or an alloy thereof. The first redistribution wiring may be formed by a deposition process such as a plating process, an electroless plating process, and a vapor deposition process.

In particular, a first bonding pad 112 may be disposed in the first lower insulating layer 110. The first bonding pad 112 may be a bump pad. The bump pad may include or may be a solder pad or a pillar pad. For example, the first bonding pad may include or may be formed of copper (Cu), aluminum (Al), tin (Sn), nickel (Ni), gold (Au), platinum (Pt), or an alloy thereof.

The second lower insulating layer 120 may be formed on the first lower insulating layer 110, and the first lower redistribution wiring 122 may be formed on the second lower insulating layer 120. The first lower redistribution wiring 122 may be electrically connected to the first bonding pad 112 through a first opening formed in the second lower insulating layer 120.

The third lower insulating layer 130 may be formed on the second lower insulating layer 120, and the second lower redistribution wiring 132 may be formed on the second lower insulating layer 130. The second lower redistribution wiring 132 may be electrically connected to the first lower redistribution wiring 122 through a second opening formed in the third lower insulating layer 130.

The fourth lower insulating layer 140 may be formed on the third lower insulating layer 130, and the third lower redistribution wiring 142 may be formed on the third lower insulating layer 130. The third lower redistribution wiring 142 may be electrically connected to the second lower redistribution wiring 132 through a third opening formed in the third lower insulating layer 130.

A second bonding pad 160 may be disposed on the third lower redistribution wiring 142. A solder resist layer as the fifth lower insulating layer 150 may be formed on the fourth lower insulating layer 140 and expose at least a portion of the second bonding pad 160. The solder resist layer 150 may serve as a passivation layer.

The number, size, and/or arrangement of the lower insulating layers and the lower redistribution wirings in the lower redistribution layer are provided as examples, and it will be understood that the present invention is not limited thereto.

In example embodiments, when viewed from a plan view, the lower redistribution layer 100 may include a first region R1 overlapping the semiconductor chip 200 mounted on an upper surface of the lower redistribution layer 100 and a second region R2 surrounding the first region R1. The second region R2 may be a fan-out region outside a region where the semiconductor chip 200 is disposed.

The second bonding pad 160 may be exposed from the upper surface of the lower redistribution layer 100. The second bonding pad 160 may include chip-connection bonding pads 161 formed on the uppermost third lower redistribution wirings 142 that are disposed in the first region R1 and conductive structure-connection bonding pads 162 formed on the uppermost third lower redistribution wirings 142 that are disposed in the second region R2.

In example embodiments, the semiconductor chip 200 may have a plurality of chip pads 210 that are disposed on a first surface 202, that is, an active surface. A plurality of transistors may be formed at the active surface. The semiconductor chip 200 may be mounted on the lower redistribution layer 100 such that the first surface on which the chip pads 210 are formed faces the lower redistribution layer 100.

The semiconductor chip 200 may be mounted on the lower redistribution layer 100 by a flip chip bonding method. The semiconductor chip 200 may be mounted on the lower redistribution layer 100 via conductive bumps 220. The conductive bump 220 may be disposed between the chip-connection bonding pad 161 that is disposed on the third lower redistribution wiring 142 of the lower redistribution layer 100 and the chip pad 210 of the semiconductor chip 200 and may electrically connect the semiconductor chip 200 and the first redistribution wiring 102 with each other. For example, the conductive bump 220 may include a pillar bump formed on the chip pad 210 of the semiconductor chip 200 and a solder bump formed on the pillar bump. Alternatively, the conductive bump 220 may include a solder bump formed on the chip pad 210 of the semiconductor chip 200. An underfill member 230 may be disposed between the semiconductor chip 200 and the lower redistribution layer 100.

Although only a few chip pads are illustrated in the figures, the structures and arrangements of the chip pads are provided as examples, and it will be understood that the present invention is not limited thereto. In addition, although only one semiconductor chip is illustrated in the figures, it is not limited thereto, and a plurality of semiconductor chips may be stacked on the lower redistribution layer.

In example embodiments, the sealing member 300 may cover the at least a portion of the semiconductor chip 200 that is disposed on the upper surface of the lower redistribution layer 100. The sealing member 300 may include a first molding portion covering an upper surface 204 (i.e., a backside surface or a second surface) of the semiconductor chip 200 and a second molding portion covering the upper surface of the lower redistribution layer 100 around the semiconductor chip 200.

For example, the sealing member 300 may include or may be formed of an epoxy mold compound (EMC). The sealing member 300 may be formed by a molding process, a screen printing process, or a lamination process.

In example embodiments, the plurality of vertical conductive structures 400 may extend in a vertical direction to penetrate the sealing member 300. The plurality of vertical conductive structures 400 may be formed on the conductive structure-connection bonding pads 162 that are disposed on the uppermost third lower redistribution wirings 142 of the second region R2.

The vertical conductive structure 400 may penetrate sealing member 300 and serve as an electrical connection path. The vertical conductive structure 400 may serve as a through mold via (TMV) extending through the second molding portion of the sealing member 300. That is, the vertical conductive structures 400 may be disposed on the fan-out region R2 outside the region where the semiconductor chip 200 is disposed and may electrically connect the lower redistribution layer 100 and the upper redistribution layer 500 with each other.

In example embodiments, the upper redistribution layer 500 may be disposed on the sealing member 300 and may include second redistribution wirings 502 electrically connected to the vertical conductive structures 400, respectively. The second redistribution wirings 502 may include upper redistribution wirings 512 and 522 stacked in at least two layers that are disposed on the upper surface 302 of the sealing member 300. The second redistribution wirings 502 may be disposed on the sealing member 300 to serve as backside redistribution wirings. Accordingly, the upper redistribution layer 500 may be a backside redistribution layer (BRDL) of the fan-out package.

The second redistribution wirings 502 may include first upper redistribution wiring 512 and second upper redistribution wiring 522 stacked in two layers. In this case, the second upper redistribution wiring 522 may correspond to an uppermost second redistribution wiring among the second redistribution wirings.

A first upper insulating layer 510 may be disposed on the upper surface 302 of the sealing member 300 and include openings that expose upper surfaces of the vertical conductive structures 400. The first upper redistribution wirings 512 may be formed on the first upper insulating layer 510 and at least portions of the first upper redistribution wirings 512 may contact the vertical conductive structures 400 through the openings. The term “contact,” as used herein, refers to a direct connection (i.e., touching) unless the context indicates otherwise.

A second upper insulating layer 520 may be disposed on the first upper insulating layer 510 and include openings that expose the first upper redistribution wirings 512. The second upper redistribution wirings 522 may be formed on the first upper insulating layer 510 and at least portions of the second upper redistribution wirings 522 may contact the first upper redistribution wirings 512 through the openings. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Although not illustrated in the figures, upper bonding pads may be disposed on the second upper redistribution wirings 522, respectively. A third upper insulating layer 530 may be disposed on the second upper insulating layer 520 and expose at least portions of the upper bonding pads. The third upper insulating layer 530 may serve as a passivation layer.

For example, the first to third upper insulating layers 510, 520, and 530 may include or may be formed of a polymer or a dielectric layer. The first to third upper insulating layers 510, 520, and 530 may include or may be formed of an insulating film such as PID and Ajinomoto build-up film (ABF). The second redistribution wirings may include or may be formed of copper (Cu), aluminum (Al), tin (Sn), nickel (Ni), gold (Au), platinum (Pt), or an alloy thereof.

The number and arrangement of the upper insulating layers and the upper redistribution wirings of the upper redistribution layer are provided as examples, and it will be understood that the present invention is not limited thereto.

As illustrated in FIG. 2, the conductive structure-connection bonding pads 162 that are exposed at the upper surface of the lower redistribution layer 100 may be disposed on the second region R2. A plating pattern 164 may be disposed on the conductive structure-connection bonding pad 162. For example, the plating pattern 164 may include or may be formed of nickel (Ni), gold (Au), or titanium (Ti).

The vertical conductive structure 400 may extend upwardly on the conductive structure-connection bonding pads 162. A first photoresist layer of a positive type and a second photoresist layer of a negative type may be formed sequentially on the upper surface of the lower redistribution layer 100, and a second opening with a relatively large aspect ratio (first aspect ratio) may be formed in the second photoresist layer, and a first opening with a relatively small aspect ratio (second aspect ratio) may be formed in the first photoresist layer, and the first and second openings may be filled up with a conductive material to form the vertical conductive structure 400. An aspect ratio of an opening may be a value of a height divided by a bottom width. For example, the first aspect ratio of the second opening may be a value of the first length L3 divided by the second diameter D32, and the second aspect ratio of the first opening may be a value of the third length L1 divided by the diameter D12.

The vertical conductive structures 400 may include first to third conductive pillar portions 410, 420 and 430 sequentially stacked and integrally formed with each other.

The first conductive pillar portion 410 may have a first tapered shape. An upper portion (i.e., an upper surface) of the first conductive pillar portion 410 may have a first diameter D11, and a lower portion (i.e., a lower surface) of the first conductive pillar portion 410 may have a second diameter D12. The second diameter D12 may be smaller than the first diameter D11. A sidewall of the first conductive pillar portion 410 may have a first angle IA1 from a horizontal direction. The first angle IA1 may be an acute angle selected from a range of 40 degrees to 80 degrees. The sidewall of the first conductive pillar portion 410 may have a positive slope. In some embodiments, the first conductive pillar portion 410 may have an increasing diameter in the vertical direction.

The second conductive pillar portion 420 may be disposed on the first conductive pillar portion 410. The second conductive pillar portion 420 may have a tapered shape or a cylindrical shape. A diameter D2 of the second conductive pillar portion 420 may be equal or smaller than the first diameter D11 of the upper portion of the first conductive pillar portion 410. A sidewall of the second conductive pillar portion 420 may have a second angle IA2 from the horizontal direction. The second angle IA2 may be an angle selected from a range of 80 degrees to 100 degrees.

The third conductive pillar portion 430 may be disposed on the second conductive pillar portion 420. The third conductive pillar portion 430 may have a tapered shape. An upper portion of the third conductive pillar portion 430 may have a third diameter D31 and a lower portion of the third conductive pillar portion 430 may have a fourth diameter D32. The fourth diameter D32 may be greater than the third diameter D31. A sidewall of the third conductive pillar portion 430 may have a third angle IA3 from the horizontal direction. The third angle IA3 may be an angle selected from a range of 80 degrees to 100 degrees. The sidewall of the third conductive pillar portion 430 may have a negative slope. In some embodiments, the third conductive pillar portion 430 may have a decreasing diameter in the vertical direction. In some embodiments, the third angle IA3 may be greater than the first angle IA1. The first and third angles IA1 and IA3 may be measured counter-clockwise from an imaginary horizontal line extending in the horizontal direction toward sidewalls of the first and third conductive pillar portions 410 and 430, respectively.

The first conductive pillar portion 410 may have a first length L1, and the third conductive pillar portion 430 may have a third length L3 greater than the first length L1. The second conductive pillar portion 420 may have a second length L2 smaller than the first length L1. The third length L3 may be at least 1.5 times the first length L1. The first conductive pillar portion 410 may have a first aspect ratio, and the third conductive pillar portion 430 may have a second aspect ratio greater than the first aspect ratio. The diameter D11 of the upper portion of the first conductive pillar portion 410 opposite to a portion bonded to (i.e., connected to) the conductive structure-connection bonding pad 162 may be greater than the diameter D32 of the lower portion of the third conductive pillar portion 430. An aspect ratio of a conductive pillar portion may be a value of a height divided by a bottom width. For example, the first aspect ratio of the first conductive pillar portion 410 may be a value of the first length L1 divided by the second diameter D12, and the second aspect ratio of the third conductive pillar portion 430 may be a value of the third length L3 divided by the diameter D32.

In example embodiments, the external connection members 550 may be disposed on the first bonding pads 112 on the outer surface of the lower redistribution layer 100. For example, the external connection member 550 may include or may be a solder ball. The solder ball may have a diameter of 300 μm to 500 μm. The fan-out wafer level package 10 may be mounted on a module substrate (not shown) via the solder balls to form a memory module.

As mentioned above, the fan-out wafer level package 10 as a fan-out wafer level package may include the lower redistribution layer 100, the semiconductor chip 200 disposed on the lower redistribution layer 100, the sealing member 300 covering at least a portion of the semiconductor chip 200 that is disposed on the upper surface of the lower redistribution layer 100, the plurality of vertical conductive structures 400 penetrating the sealing member 300, and the upper redistribution layer 500 that is disposed on the upper surface 302 of the sealing member 300.

The conductive structure-connection bonding pads 162 may be respectively disposed on the uppermost third lower redistribution wirings 142 in the second region R2 of the lower redistribution layer 100. The vertical conductive structures 400 may be bonded on (i.e., may be connected to) the conductive structure-connection bonding pads 162. The vertical conductive structures 400 may include the first to third conductive pillar portions 410, 420, and 430 sequentially stacked and integrally formed with each other. The first conductive pillar portion 410 may have the first aspect ratio and the third conductive pillar portion 430 may have the second aspect ratio greater than the first aspect ratio.

The first photoresist layer of a positive type and the second photoresist layer of a negative type may be formed sequentially, openings may be formed in the first and second photoresist layer, and then, the openings may be filled up with a conductive material to form the vertical conductive structure 400. Accordingly, the vertical conductive structures 400 as copper posts having a large aspect ratio may be formed without generating residues under the photoresist layer. For example, when a hole for a vertical conductive structure with a height of the sum of the first length L1 and the third length L3 of FIG. 2 is formed using only a negative type photoresist layer, light may not fully develop the negative film in a photolithography process, and thus the opening cannot be formed, or even if the opening is formed, a diameter of the opening at the bottom (corresponding to the second diameter D12 of FIG. 2) may be greater than a width of the conductive structure-connection bonding pad 162, which may cause electrical short between two adjacent vertical conductive structures.

Hereinafter, a method of manufacturing the semiconductor package of FIG. 1 will be described.

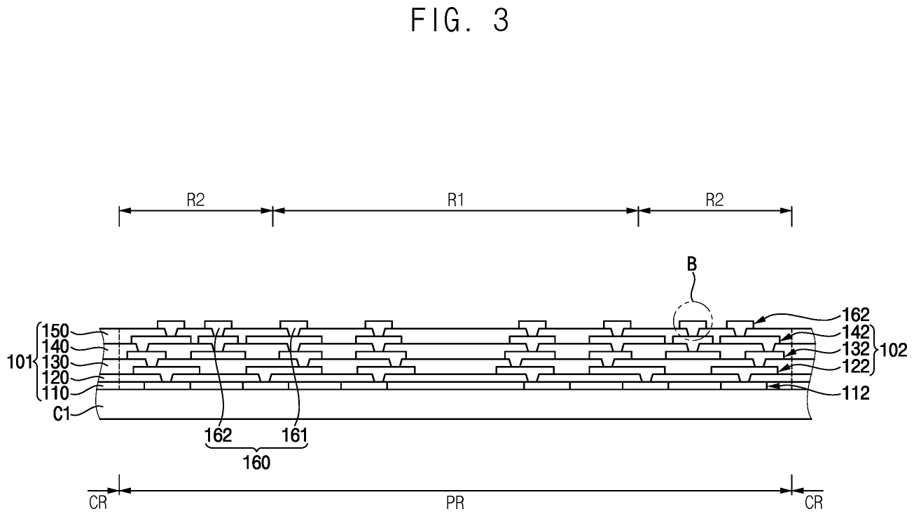

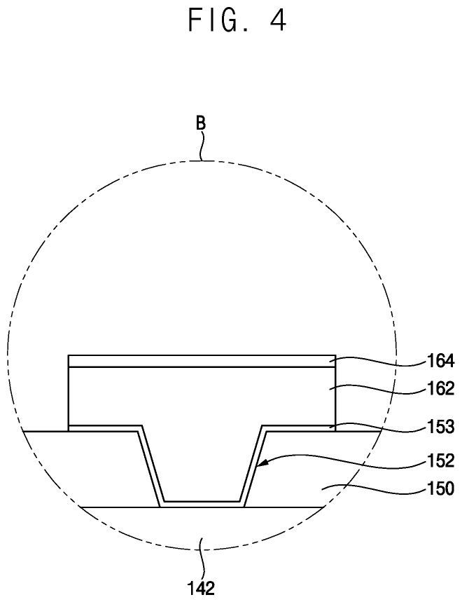

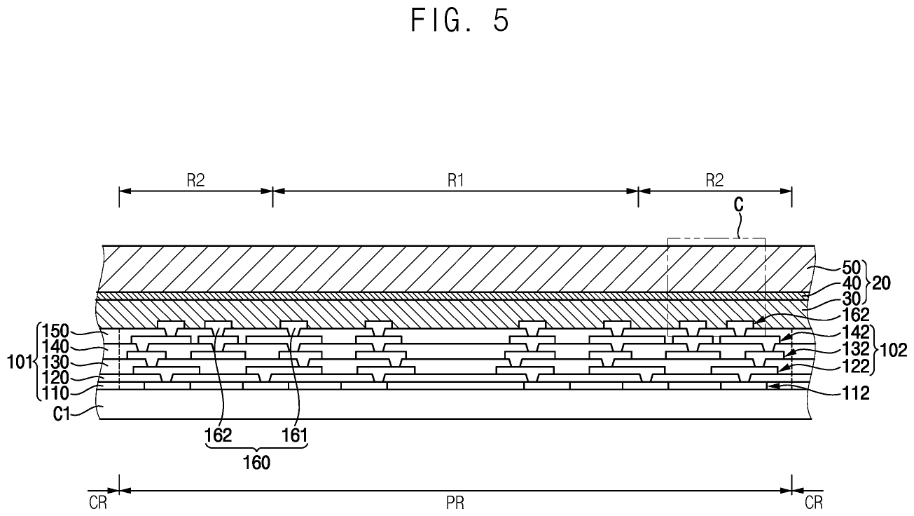

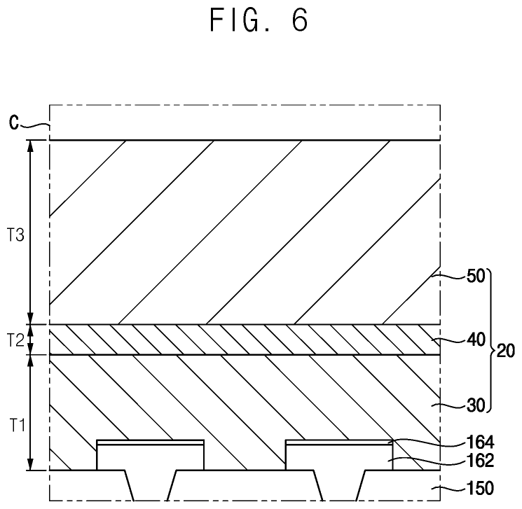

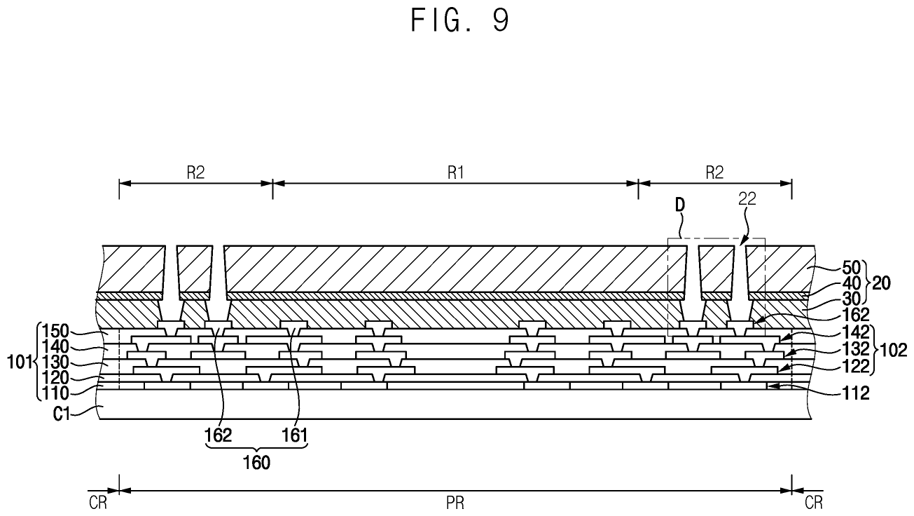

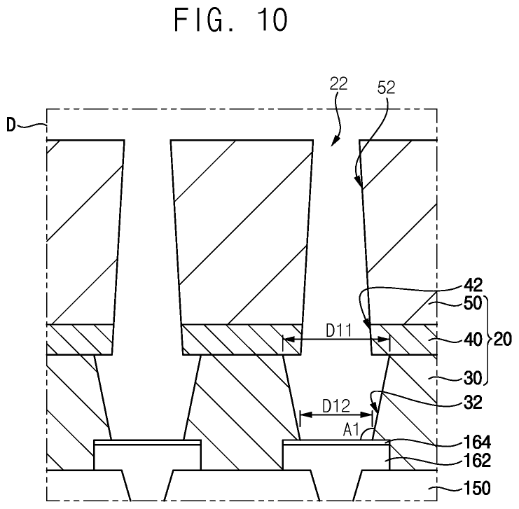

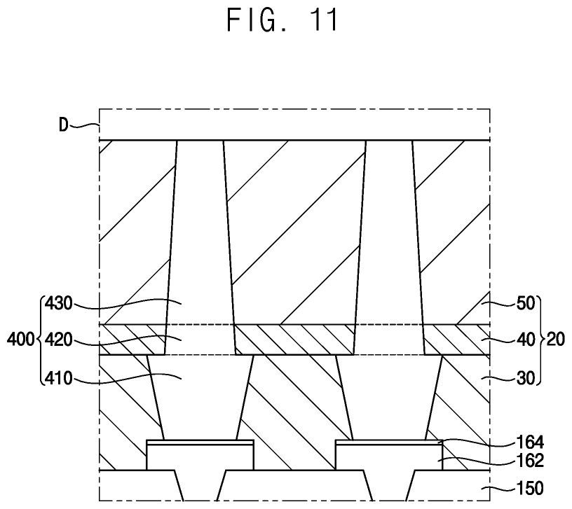

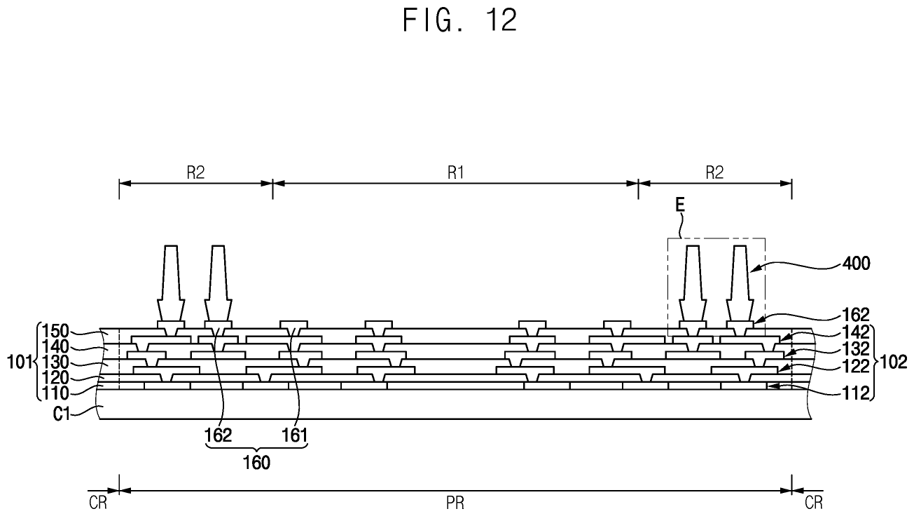

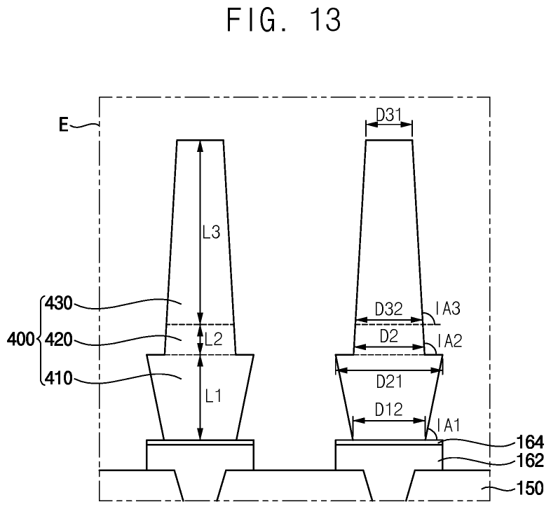

FIGS. 3 to 16 are views illustrating a method of manufacturing a semiconductor package in accordance with example embodiments. FIGS. 3, 5, 9, 12, and 14 to 16 are cross-sectional views illustrating a method of manufacturing a semiconductor package in accordance with example embodiments. FIG. 4 is an enlarged cross-sectional view illustrating portion ‘B’ in FIG. 3. FIGS. 6 to 8 are enlarged cross-sectional views illustrating portion ‘C’ in FIG. 5. FIGS. 10 and 11 are enlarged cross-sectional views illustrating portion ‘D’ in FIG. 9. FIG. 13 is an enlarged cross-sectional view illustrating portion ‘E’ in FIG. 12.

Referring to FIGS. 3 and 4, a lower redistribution layer 100 having first redistribution wirings 102 may be formed on a carrier substrate C1.

In example embodiments, the carrier substrate C1 may include or may be a wafer substrate as a base substrate on which a plurality of semiconductor chips are disposed. The semiconductor chips may be disposed on the lower redistribution layer, and a sealing member may be formed to cover the plurality of semiconductor chips. The carrier substrate C1 may have a shape corresponding to a wafer on which a semiconductor process is performed. For example, the carrier substrate C1 may include or may be a silicon substrate, a glass substrate, or a non-metal or metal plate.

The carrier substrate C1 may include a package region PR on which the semiconductor chip is mounted and a cutting region CR surrounding the package region PR. As will be described later, the lower redistribution layer 100 formed on the carrier substrate C1 and the sealing member may be cut along the cutting region CR to be individualized into a plurality of the package regions MR.

In example embodiments, a first lower insulating layer 110 in which first bonding pads 112 are formed may be formed on the carrier substrate C1. Although not illustrated in the figures, a release layer, a barrier metal layer, a seed layer and the first lower insulating layer may be formed on the carrier substrate C1, and then, the first lower insulating layer may be patterned to form openings that expose first bonding pad regions. Then a plating process may be performed on the seed layer to form the first bonding pads 112 in the openings.

For example, the first lower insulating layer 110 may include or may be a polymer layer or a dielectric layer. The first lower insulating layer 110 may include or may be an insulating film such as PID and ABF. The first lower insulating layer may be formed by a spin coating process or a vapor deposition process.

The first bonding pad 112 may be a bump pad. The bump pad may include or may be a solder pad or a pillar pad. For example, the first bonding pad may include or may be formed of copper (Cu), aluminum (Al), tin (Sn), nickel (Ni), gold (Au), platinum (Pt), or an alloy thereof.

Then, a second lower insulating layer 120 may be formed on the first lower insulating layer 110 to cover the first bonding pads 112, and then, the second lower insulating layer 120 may be patterned to form first openings that expose the first bonding pads 112, respectively.

For example, the second lower insulating layer 120 may include or may be a polymer layer or a dielectric layer. The second lower insulating layer 120 may include or may be an insulating film such as PID and ABF. The second lower insulating layer may be formed by a spin coating process or a vapor deposition process.

Then, first lower redistribution wirings 122 may be formed on the second lower insulating layer 120 to contact the first bonding pads 112 through the first openings, respectively.

After a seed layer is formed on a portion of the second lower insulating layer 120 and in the first opening, the seed layer may be patterned and an electroplating process may be performed to form the first lower redistribution wirings 122. Accordingly, at least portions of the first lower redistribution wirings 122 may contact the first bonding pads 112 through the first openings.

For example, the first lower redistribution wirings 122 may include or may be formed of copper (Cu), aluminum (Al), tin (Sn), nickel (Ni), gold (Au), platinum (Pt), or an alloy thereof.

Similarly, a third lower insulating layer 130 may be formed on the second lower insulating layer 120 to cover the first lower redistribution wirings 122, and the third lower insulating layer 130 may be patterned to form second openings that expos at least portions of the first lower redistribution wirings 122. Then, second lower redistribution wirings 132 may be formed on the third lower insulating layer 130 to contact the first lower redistribution wirings 122 through the second openings, respectively.

Then, a fourth lower insulating layer 140 may be formed on the third lower insulating layer 130 to cover the second lower redistribution wirings 132, and the fourth lower insulating layer 140 may be patterned to form third openings that expose at least portions of the second lower redistribution wirings 132. Then, the third lower redistribution wirings 142 may be formed on the fourth lower insulation layer 140 to contact the second lower redistribution wirings 132 through the second openings, respectively.

Then, after a fifth lower insulating layer 150 is formed on the fourth lower insulating layer 140 to cover the third lower redistribution wirings 142, the fifth lower insulating layer 150 may be patterned to form fourth openings that expose at least portions of the third lower redistribution wirings 142.

Accordingly, the lower redistribution layer 100 having the first to fifth lower insulating layers 110, 120, 130, 140 and 150 may be formed. The lower redistribution layer 100 may be a front redistribution layer (FRDL) of a fan-out package. The lower redistribution layer 100 may include first to third lower redistribution wirings 122, 132 and 142 stacked in at least two layers. The first bonding pads 112 may be exposed from a lower surface of the lower redistribution layer 100.

As will be described later, when viewed from a plan view, the lower redistribution layer 100 may include a first region R1 overlapping a semiconductor chip mounted on the lower redistribution layer 100 and a second region R2 surrounding the first region R1. The second region R2 may be a fan-out region outside the first region R1 where the semiconductor chip is disposed.

Then, second bonding pad 160 may be formed on the uppermost third lower redistribution wirings 142 of the lower redistribution layer 100.

For example, a seed layer may be formed on the fifth lower insulating layer 150, and a photoresist pattern having an opening exposing a second bonding pad region may be formed on the seed layer. Then, the second bonding pad 160 may be formed in the openings of the photoresist pattern by a plating process.

Accordingly, the second bonding pad 160 may be formed on the uppermost third lower redistribution wirings 142 that are disposed in the first region R1 and the second region R2 of the lower redistribution layer 100. The second bonding pad 160 may include chip-connection bonding pads 161 that are formed on the uppermost third lower redistribution wirings 142 of the first region R1 and conductive structure-connection bonding pads 162 that are formed on the uppermost third lower redistribution wirings 142 of the second region R2.

As illustrated in FIG. 4, a plating pattern 164 may be formed on a corresponding one of the conductive structure-connection bonding pads 162. The plating pattern 164 may be formed by performing a plating process on the conductive structure-connection bonding pads 162. For example, the plating pattern 164 may include or may be formed of nickel (Ni), gold (Au), or titanium (Ti). Then, the photoresist pattern may be removed from the fifth lower insulating layer 150, and a portion of the seed layer exposed by the conductive structure-connection bonding pads 162 may be removed to form a seed layer pattern 153.

Referring to FIGS. 5 to 13, vertical conductive structures 400 may be formed on the conductive structure-connection bonding pads 162 that are disposed in the fan-out region R2.

As illustrated in FIGS. 5 and 6, a photosensitive insulating material layer 20 may be formed on an upper surface of the lower redistribution layer 100 to cover the second bonding pad 160. In particular, a first photosensitive insulating layer 30, a light blocking layer 40 and a second photosensitive insulating layer 50 may be sequentially formed on the fifth lower insulating layer 150 of the lower redistribution layer 100. The first and second photosensitive insulating layers 30 and 50 may include or may be formed of a polymer material that hardens or softens in response to light.

The first photosensitive insulating layer 30 may include or may be formed of a positive photosensitive insulating material. A molecular structure of the positive photosensitive insulating material may be destroyed in response to the light. The second photosensitive insulating layer 50 may include or may be formed of a negative photosensitive insulating material. A molecular structure of the negative photosensitive insulating material may be more strongly bonded in response to the light.

The first photosensitive insulating layer 30 may have a first thickness T1 on the lower redistribution layer 100. The light blocking layer 40 may have a second thickness T2. The second photosensitive insulating layer 50 may have a third thickness T3. For example, the third thickness T3 may be greater than the first thickness T1. The third thickness T3 may be at least 1.5 times the first thickness T1. The first to third thicknesses T1, T2 and T3 may be determined in consideration of an aspect ratio of the vertical conductive structure 400 to be formed in the photosensitive insulating material layer 20 and/or developing conditions of a photo process.

For example, the first and second photosensitive insulating layers 30 and 50 may include or may be formed of polyimide, plumbate oxide, poly hydroxystylene, benzocyclobutene, or acryl. The light blocking layer 40 may include metal oxide, metal nitride, metal carbide, metal boride, organic materials, organic resin, inorganic filler, or organic filler.

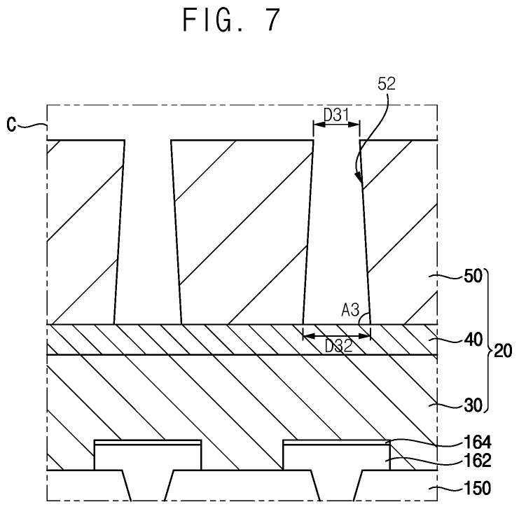

As illustrated in FIG. 7, third openings 52 may be formed in the second photosensitive insulating layer 50 to penetrate the second photosensitive insulating layer 50.

In particular, a first mask may be disposed on the second photosensitive insulating layer 50 and light may be irradiated onto the first mask. The light may include or may be extreme ultraviolet (EUV).

The first mask may have a first opening pattern corresponding to the third openings 52. At least a portion of the light may be irradiated onto the second photosensitive insulating layer 50 through the first opening pattern, and at least other portion of the light may be blocked by the first mask. A molecular structure in a portion of the second photosensitive insulating layer 50 irradiated by the light may be more strongly bonded. A portion of the second photosensitive insulating layer 50 not irradiated by the light may be removed to form the third openings 52. In some embodiments, the portion of the second photosensitive insulating layer 50 irradiated by the light may be affected by light reflected from an inner sidewall of the first mask and/or an upper surface of the light blocking layer 40.

The portion of the second photosensitive insulating layer 50 not irradiated by the light may be removed through a wet developing process using a developing solution or a dry developing process using a developing gas. For example, the developing solution may include or may be formed of tetramethylammonium hydroxide (TMAH). The developing gas may include or may be hydrogen (H₂), chlorine (Cl₂), fluorine (F₂), bromine (Br₂), iodine (I₂), hydrogen chloride (HCl), hydrogen fluoride (HF), hydrogen bromide (HBr), or hydrogen iodide (HI).

Since the light has straightness, a sidewall of the third openings 52 formed in the second photosensitive insulating layer 50 may have a relatively small slope. Since the sidewall of the third openings 52 has a relatively small slope, the third openings 52 may be formed to have a relatively large depth. As the depth of the third openings 52 increases, a length of the vertical conductive structure may be greater.

The light irradiated onto the second photosensitive insulating layer 50 may be blocked by the light blocking layer 40. The light blocking layer 40 may prevent the light from being irradiated onto the first photosensitive insulating layer 30.

The third opening 52 may have a second tapered shape. An upper portion of the third opening 52 may have a third diameter D31 and a lower portion of the third opening 52 may have a fourth diameter D32. The fourth diameter D32 may be greater than the third diameter D31. A sidewall of the third opening 52 may have a third angle A3 from a horizontal direction. The third angle A3 may be an angle selected from a range of 80 degrees to 100 degrees. The sidewall of the third opening 52 may have a negative slope due to the negative type photoresist.

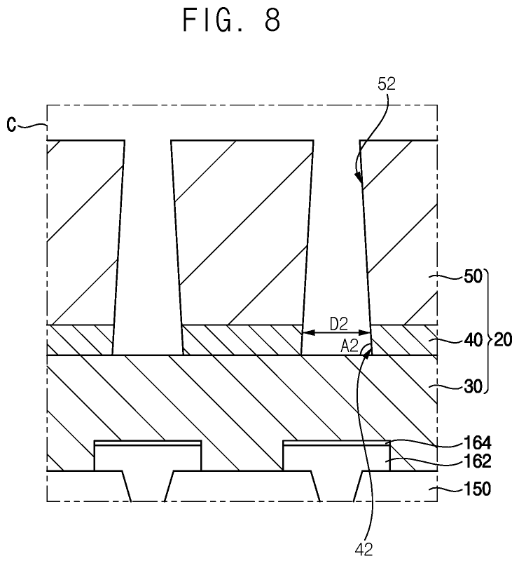

As illustrated in FIG. 8, second openings 42 may be formed in the light blocking layer 40 to be in communication with the third openings 52 respectively. The light blocking layer 40 exposed from the third openings 52 of the second photosensitive insulating layer 50 may be removed to form the second openings 42. For example, the light blocking layer 40 may be removed by a plasma descum process.

The second opening 42 may have a tapered or cylindrical shape similar to the third opening 52. The diameter D2 of the second opening 42 may be equal to or greater than the second diameter D32 of the lower portion of the third opening 52. A sidewall of the second opening 42 may have a second angle A2 from the horizontal direction. The second angle A2 may be an angle selected from a range of 80 degrees to 100 degrees.

As illustrated in FIGS. 9 and 10, first openings 32 may be formed in the first photosensitive insulating layer 30 to be in communication with the second openings 42.

In particular, light may be irradiated onto the first photosensitive insulating layer 30 exposed through the third and second openings 52 and 42.

A second mask may be disposed on the second photosensitive insulating layer 50 and light may be irradiated onto the second mask. The second mask may have a second opening pattern corresponding to the first openings 32. At least a portion of the light passing through the second opening pattern may be radiated onto the first photosensitive insulating layer 30, and at least other portion of the light may be blocked by the second mask.

Alternatively, the light may be irradiated onto the second photosensitive insulating layer 50 without disposing the second mask. Since the second photosensitive insulating layer 50 is hardened by the light, the light may be radiated onto the first photosensitive insulating layer 30 at once when the light is radiated onto the second photosensitive insulating layer 50.

A molecular structure in a portion of the first photosensitive insulating layer 30 irradiated by the light may collapse in response to the light. The portion of the first photosensitive insulating layer 30 irradiated by the light may be removed to form the first openings 32. In some embodiments, the portion of the first photosensitive insulating layer 30 irradiated by the light may be affected by light reflected from an inner sidewall of the second opening 42 of the light blocking layer 40 and/or an upper surface of the plating pattern 164 and/or the conductive structure-connection bonding pad 162.

When light having a strong light intensity is irradiated onto the first photosensitive insulating layer 30, the molecular structure of the portion of the first photosensitive insulating layer 30 irradiated by the light may be completely decomposed, leaving no residue. The portion of the first photosensitive insulating layer 30 may be removed by a vapor developing process or a gas developing process.

The first opening 32 of the first photosensitive insulating layer 30 may have a first tapered shape. An upper portion of the first opening 32 may have a first diameter D11 and a lower portion of the first opening 32 may have a second diameter D12. The second diameter D12 may be smaller than the first diameter D11. A sidewall of the first opening 32 may have a first angle A1 from the horizontal direction. The first angle A1 may be an obtuse angle selected from a range of 100 degrees to 140 degrees. The sidewall of the first opening 32 may have a positive slope by using the positive type photoresist.

Accordingly, a through hole 22 having the first to third openings 32, 42 and 52 communicating with each other may be formed in the photosensitive insulating material layer 20 that is disposed on the upper surface of the lower redistribution layer 100. The first to third openings 32, 42, and 52 may be connected with each other to form the through hole 22. The through hole 22 may have a relatively large aspect ratio. The conductive structure-connection bonding pads 162 may be exposed by a bottom surface of the through hole 22. In some embodiments, the through hole 22 may a lower portion having an increasing diameter in the vertical direction and an upper portion having a decreasing diameter in the vertical direction. The through hole 22 may have a kink between the lower portion and the upper portion.

Since the first photosensitive insulating layer 30 including a positive type photoresist reacts in proportion to an amount of light absorbed, the first opening 32 may have a tapered shape after the development process, so that the diameter D11 of the upper portion of the first opening 32 may be larger than the diameter D12 of the lower portion of the first opening 32. Further, if the amount of light is increased, the residue in the lower portion of the first opening 32 may be completely removed. However, when the thickness of the first photosensitive insulating layer 30 increases, an influence of a tapered positive slope becomes very large, so there may be limitations in forming an opening having a large aspect ratio.

Meanwhile, the second photosensitive insulating layer 50 including the negative type photoresist may become hydrophobic due to cross-linking at a portion absorbing UV light. Accordingly, an opening with a relatively small tapered shape, that is, a large aspect ratio may be formed due to the straightness of the UV light. However, due to UV reflection at unintended interface, the photoresist may be hardened, resulting in residue.

In example embodiments, the second photosensitive insulating layer 50 may be formed on the first photosensitive insulating layer 30, the third opening 52 having a relatively large aspect ratio (first aspect ratio) may be formed in the second photosensitive insulating layer 50, and the first opening 32 having a relatively small aspect ratio (second aspect ratio) may be formed in the first photosensitive insulating layer 30. Accordingly, the vertical conductive structure 400 as a Cu-post having a large aspect ratio may be formed by a subsequent plating process without a residue.

As illustrated in FIGS. 11 to 13, the through holes 22 of the photosensitive insulating material layer 20 may be filled up with a conductive material by performing an electrolytic plating process to form the vertical conductive structures 400. Then, the photosensitive insulating material layer 20 may be removed by a strip process. For example, the vertical conductive structure 400 may include or may be formed of Cu. A lower portion of the vertical conductive structure 400 may be bonded to the plating pattern 164 on the conductive structure-connection bonding pads 162. In some embodiments, the lower portion of the vertical conductive structure 400 may be connected to the plating pattern 164.

The vertical conductive structure 400 may extend upward from the conductive structure-connection bonding pads 162. The vertical conductive structures 400 may be electrically connected to the first redistribution wirings 102. As will be described later, the vertical conductive structure 400 may be provided to penetrate the sealing member to serve as an electrical connection path. That is, the through vertical conductive structures 400 may be disposed in the fan-out region R2 outside the region where the semiconductor chip (die) is disposed to be used for electrical connection.

The vertical conductive structures 400 may include first to third conductive pillar portions 410, 420 and 430 respectively disposed in the first to third openings 32, 42 and 52 of the photosensitive insulating material layer 20.

The first conductive pillar portion 410 may have the first tapered shape corresponding to the shape of the first opening 32. An upper portion of the first conductive pillar portion 410 may have the first diameter D11 and a lower portion of the first conductive pillar portion 410 may have the second diameter D12. The second diameter D12 may be smaller than the first diameter D11. A sidewall of the first conductive pillar portion 410 may have a first angle IA1 from the horizontal direction. The first angle IA1 may be an acute angle selected from a range of 40 degrees to 80 degrees. The sidewall of the first conductive pillar portion 410 may have a positive slope.

The second conductive pillar portion 420 may be disposed on the first conductive pillar portion 410. The second conductive pillar portion 420 may have the tapered shape or the cylindrical shape corresponding to the shape of the second opening 42. The diameter D2 of the second conductive pillar portion 420 may be equal to or smaller than the first diameter D11 of the upper portion of the first conductive pillar portion 410. A sidewall of the second conductive pillar portion 420 may have a second angle IA2 from the horizontal direction. The second angle A2 may be an angle selected from a range of 80 degrees to 100 degrees.

The third conductive pillar portion 430 may be disposed on the second conductive pillar portion 420. The third conductive pillar portion 430 may have the second tapered shape corresponding to the shape of the third opening 52. An upper portion of the third conductive pillar portion 430 may have the third diameter D31 and a lower portion of the third conductive pillar portion 430 may have the fourth diameter D32. The fourth diameter D32 may be larger than the third diameter D31. A sidewall of the third conductive pillar portion 430 may have a third angle IA3 from the horizontal direction. The third angle IA3 may be an angle selected from a range of 80 degrees to 100 degrees. The sidewall of the third conductive pillar portion 430 may have a negative slope.

The first conductive pillar portion 410 may have a first length L1, and the third conductive pillar portion 430 may have a third length L3 greater than the first length L1. The third length L3 may be at least 1.5 times the first length L1. The first conductive pillar portion 410 may have the first aspect ratio, and the third conductive pillar portion 430 may have the second aspect ratio greater than the first aspect ratio. The upper diameter D11 of the first conductive pillar portion 410 opposite to the portion bonded to the conductive structure-connection bonding pads 162 may be greater than the diameter D32 of the lower portion of the third conductive pillar portion 430 adjacent to the first conductive pillar portion 410.

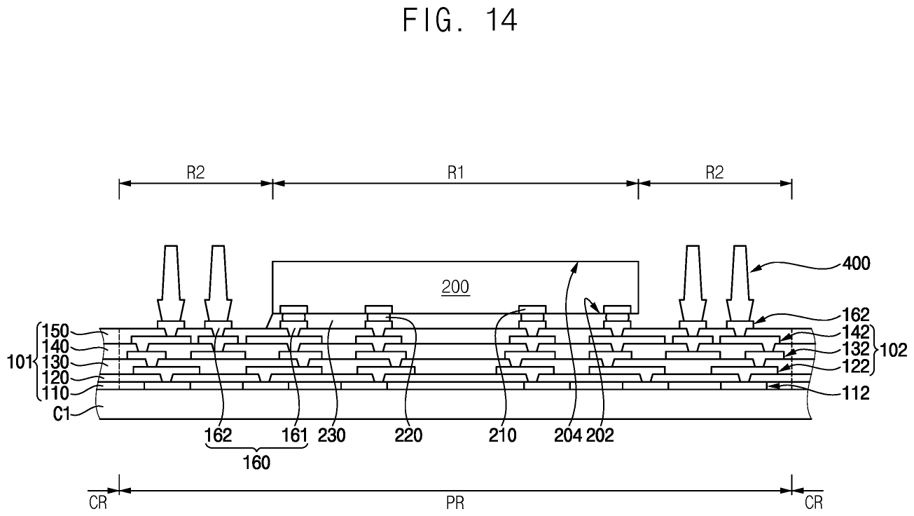

Referring to FIG. 14, at least one semiconductor chip 200 may be mounted on the upper surface of the lower redistribution layer 100.

In example embodiments, the semiconductor chip 200 may be disposed in the first region R1 that is a fan-in region of the lower redistribution layer 100. The semiconductor chip 200 may be mounted on the upper surface of the lower redistribution layer 100 by a flip chip bonding method. The semiconductor chip 200 may be disposed such that a front surface 202 on which chip pads 210 are formed, that is, an active surface of the semiconductor chip 200, faces the lower redistribution layer 100. A plurality of transistors of the semiconductor chip 200 may be formed at the active surface. The chip pads 210 of the semiconductor chip 200 may be electrically connected to the first redistribution wirings 102 of the lower redistribution layer 100 via conductive bumps 220. The conductive bumps 220 may be respectively bonded to the chip-connection bonding pads 161 on the uppermost third lower redistribution wiring 142. For example, the conductive bumps 220 may include or may be micro bumps (μBumps).

An underfill member 230 may be underfilled between the semiconductor chip 200 and the lower redistribution layer 100. The underfill member may include or may be formed of a material having relatively high fluidity to effectively fill a small space between the semiconductor chip and the lower redistribution layer. For example, the underfill member may include an adhesive containing an epoxy material.

The semiconductor chip may be a logic chip including a logic circuit. The logic chip may be a controller that controls memory chips. The semiconductor chip may be a processor chip such as ASIC or an application processor (AP) serving as a host such as a central processing unit (CPU), a graphic processing unit (GPU) and a system on a chip (SOC).

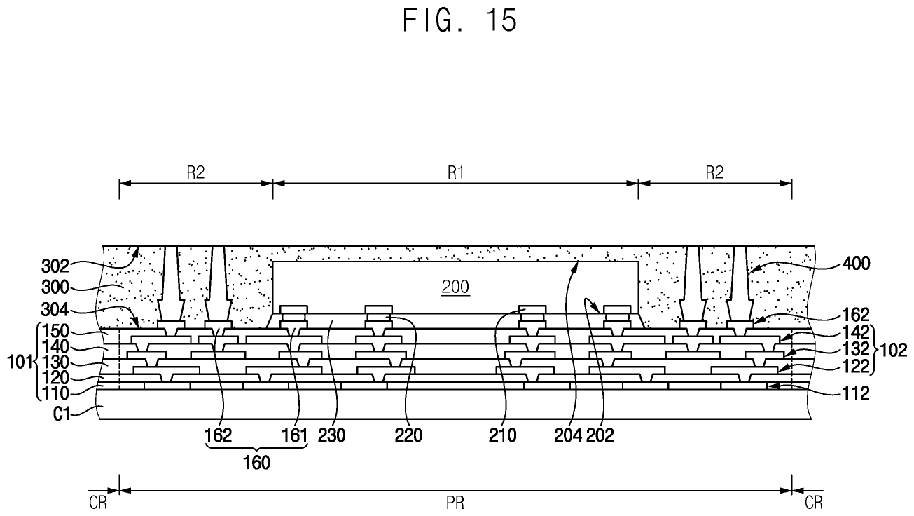

Referring to FIG. 15, a sealing member 300 that is disposed on the upper surface of the lower redistribution layer 100 may be formed to cover the semiconductor chip 200 and the plurality of vertical conductive structures 400.

First, a sealing material may be formed to cover an upper surface 204 of the semiconductor chip 200 and upper surfaces of the plurality of vertical conductive structures 400. For example, the sealing material may include or may be formed of an epoxy molding compound (EMC). The sealing material may include or may be formed of UV resin, polyurethane resin, silicone resin, or silica filler.

Then, an upper portion of the sealing material may be partially removed to form the sealing member 300 that exposes upper ends of the plurality of vertical conductive structures 400. The upper portion of the sealing material may be partially removed by a grinding process.

The sealing member 300 may include a first sealing portion covering the upper surface 204 of the semiconductor chip 200 and a second sealing portion covering the upper surface of the lower redistribution layer 100 around the semiconductor chip 200.

Accordingly, the plurality of vertical conductive structures 400 may extend to penetrate the sealing member 300 that is formed on the upper surface of the fan-out region R2 of the lower redistribution layer 100. The vertical conductive structure 400 may serve as a through mold via (TMV) extending through the second sealing portion of the sealing member 300.

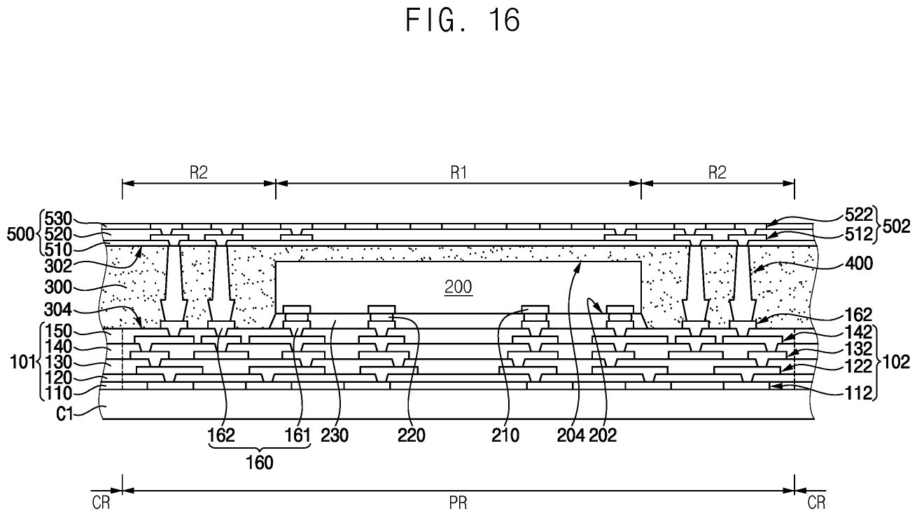

Referring to FIG. 16, an upper redistribution layer 500 having second redistribution wirings 502 electrically connected to the vertical conductive structures 400 may be formed on an upper surface 302 of the sealing member 300.

In example embodiments, after forming a first upper insulating layer 510 on the upper surface 302 of the sealing member 300, the first upper insulating layer 510 may be patterned to form openings respectively exposing upper portions of the vertical conductive structures 400. The openings of the first upper insulating layer 510 may expose the upper surfaces of the vertical conductive structures 400.

Then, after forming a seed layer on portions of the exposed vertical conductive structures 400 and in the openings, the seed layer may be patterned and an electroplating process may be performed to form first upper redistribution wirings 512. Accordingly, at least a portion of the first upper redistribution wirings 512 may be electrically connected to the vertical conductive structures 400 through the openings.

Then, after forming a second upper insulating layer 520 on the first upper insulating layer 510, the second upper insulating layer 520 may be patterned to form openings exposing the first upper redistribution wirings 512. Then, second upper redistribution wirings 522 may be formed on the second upper insulating layer 520 to contact the first upper redistribution wirings 512 through the openings.

Accordingly, the second redistribution wirings 502 may include at least two stacked layers of the first upper redistribution wiring 512 and the second upper redistribution wiring 522. In this case, the second upper redistribution wiring 522 may be an uppermost redistribution wiring among the second redistribution wirings.

Then, upper bonding pads may be formed respectively on the second upper redistribution wirings 522 as the uppermost redistribution wirings, and a third upper insulating layer 530 may be formed on the second upper insulating layer 520 to expose at least portions of the upper bonding pads on the second upper redistribution wiring 522. The third upper insulating layer 530 may serve as a passivation layer.

Then, the carrier substrate C1 may be removed, and external connection members 550 (see FIG. 1) may be formed on the first bonding pads 112 on an outer surface (i.e., a lower surface) of the lower redistribution layer 100.

Then, the lower redistribution layer 100 may be separated individually by a sawing process to complete the fan-out wafer level package 10 of FIG. 1. The fan-out wafer level package 10 may include the sealing member 300, the lower redistribution layer 100 that is formed on a lower surface 304 (i.e., a second surface) of the sealing member 300, and the upper redistribution layer 500 that is formed on the upper surface 302 of the sealing member 100.

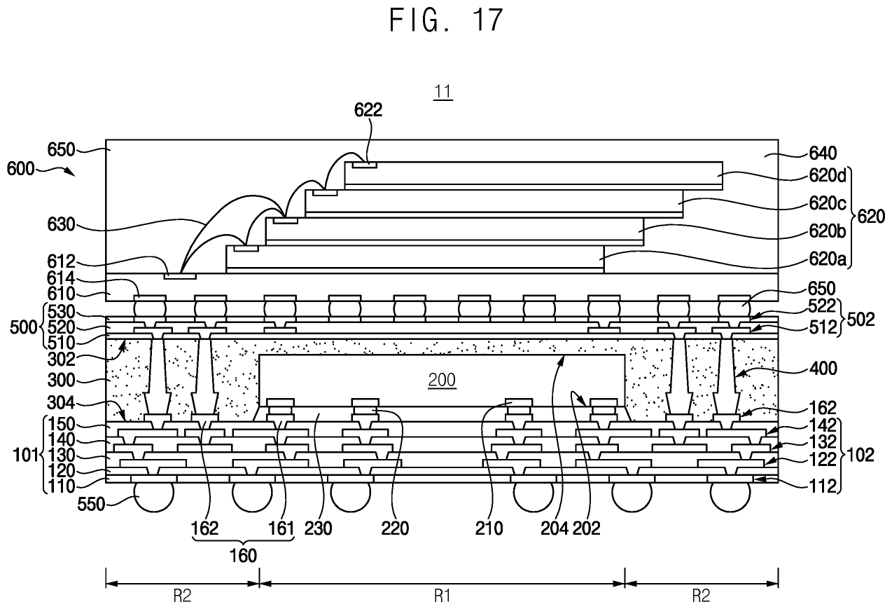

FIG. 17 is a cross-sectional view illustrating a semiconductor package in accordance with example embodiments. The semiconductor package is substantially the same as the semiconductor package described with reference to FIG. 1 except for an additional configuration of the second package. Accordingly, the same reference numerals may be used to refer to the same or like elements and any further repetitive explanation concerning the above elements will be omitted.

Referring to FIG. 17, a semiconductor package 11 may include a first package and a second package 600 stacked on the first package. The first package may include a lower redistribution layer 100, a semiconductor chip 200, a sealing member 300 and an upper redistribution layer 500. The first package may be substantially the same as or similar to the unit package described with reference to FIG. 1.

In example embodiments, the second package 600 may include a second package substrate 610, a plurality of second semiconductor chips 620 mounted on the second package substrate 610 and a sealing member 640 covering the second semiconductor chips 620 on the second package substrate 610.

The second package 600 may be stacked on the first package via conductive connection members 650. For example, the conductive connection members 650 may include or may be solder balls or conductive bumps. The conductive connection member 650 may be disposed between a bonding pad on the second upper redistribution wiring 422 of the upper redistribution layer 500 and a second connection pad 614 of the second package substrate 610. Accordingly, the first package and the second package 600 may be electrically connected with each other by the conductive connection members 650.

The plurality of second semiconductor chips 620a, 620b, 620c and 620d may be sequentially stacked on the second package substrate 610 by adhesive members. Bonding wires 630 may connect second chip pads 622 of the second semiconductor chips 620 to first connection pads 612 of the second package substrate 610. The second semiconductor chips 620 may be electrically connected to the second package substrate 610 through the bonding wires 630.

Although the second package 600 includes four semiconductor chips mounted by a wire bonding method, it will be understood that the number of the semiconductor chips in the second package and the mounting method are not limited thereto.

In example embodiments, the semiconductor package 11 may further include a heat sink (not illustrated) stacked on the second package 600. The heat sink may be disposed on the second package 600 and may dissipate heat from the first and second packages to the outside. The heat sink may be attached on the second package 600 by a thermal interface material (TIM).

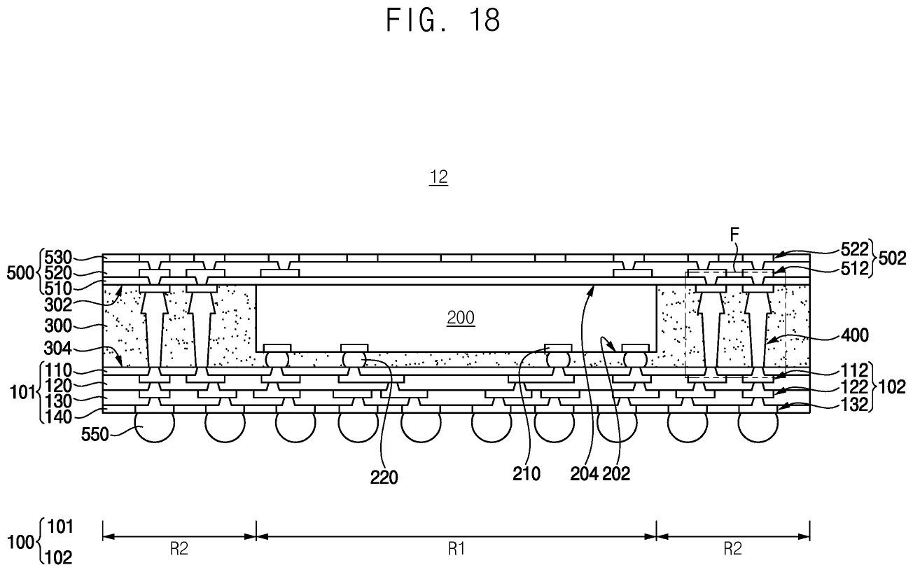

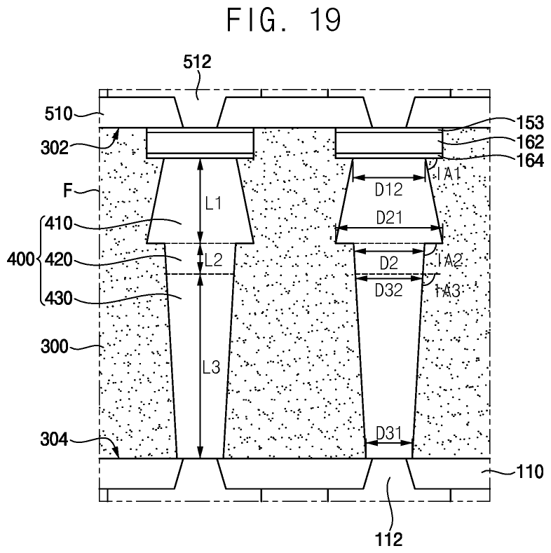

FIG. 18 is a cross-sectional view illustrating a semiconductor package in accordance with example embodiments. FIG. 19 is an enlarged cross-sectional view illustrating portion ‘F’ in FIG. 18. The semiconductor package is substantially the same as the semiconductor package described with reference to FIGS. 1 and 2 except for the arrangement of semiconductor chips and the connection structure of the vertical conductive structures. Accordingly, the same reference numerals denote the same components, and repeated description of the same components is omitted.

Referring to FIGS. 18 and 19, a fan-out wafer level package 12 may include a lower redistribution layer 100, a semiconductor chip 200 disposed on the lower redistribution layer 100, a sealing member 300 covering at least one side surface of the semiconductor chip 200 on the lower redistribution layer 100, an upper redistribution layer 500 disposed on the sealing member 300, and a plurality of vertical conductive structures 400 penetrating the sealing member 300 and electrically connecting the lower redistribution layer 100 and the upper redistribution layer 500 with each other. In addition, the fan-out wafer level package 12 may further include external connection members 550 disposed on an outside surface of the lower redistribution layer 100.

In example embodiments, the semiconductor chip 200 may have a plurality of chip pads 210 on a first surface 202, that is, an active surface thereof. The semiconductor chip 200 may be accommodated in the sealing member 300 such that the first surface 202 on which the chip pads 210 are formed faces the lower redistribution layer 100. The sealing member 300 may cover an outside surface of the semiconductor chip 200. The first surface 202 of the semiconductor chip 200 may be exposed from a second surface 304 of the sealing member 300, and the second surface 304 opposite to the first surface 202 of the semiconductor chip 200 may be exposed from a first surface 302 of the sealing member 300.

The semiconductor chip 200 may be mounted on the lower redistribution layer 100 via conductive bumps 220. The conductive bumps 220 may be disposed between a first lower redistribution wiring 112 of the lower redistribution layer 100 and a chip pad 210 of the semiconductor chip 200 and may electrically connect the semiconductor chip 200 and a first redistribution wiring 102 with each other.

The sealing member 300 may cover at least a portion of the semiconductor chip 200 on an upper surface of the lower redistribution layer 100. The sealing member 300 may include a first sealing member covering the first surface 202 of the semiconductor chip 200 and a second sealing member covering the upper surface of the lower redistribution layer 100 around the semiconductor chip 200.

In example embodiments, the plurality of vertical conductive structures 400 may extend in a vertical direction to penetrate the sealing member 300. The vertical conductive structures 400 may extend in the vertical direction from the first surface 302 of the sealing member 300 to the second surface 304. A first end portion of the vertical conductive structure 400 may be exposed from the second surface 304 of the sealing member 300.

As illustrated in FIG. 19, a plurality of conductive structure-connection bonding pads 162 may be disposed on a second end portion of the vertical conductive structure 400. A plating pattern 164 may be disposed on the conductive structure-connection bonding pad162. For example, the plating pattern 164 may include or may be formed of nickel (Ni), gold (Au), or titanium (Ti). The vertical conductive structure 400 may be bonded to the plating pattern 164.

The vertical conductive structure 400 may extend downward and may be disposed on the conductive structure-connection bonding pad 162. The vertical conductive structure 400 may be sequentially stacked from the conductive structure-connection bonding pad 162 and include first to third conductive pillar portions 410, 420 and 430 integrally formed with each other.

The first conductive pillar portion 410 may have a first tapered shape. An upper portion of the first conductive pillar portion 410 may have a first diameter D11, and a lower portion of the first conductive pillar portion 410 may have a second diameter D12. The second diameter D12 may be smaller than the first diameter D11. A sidewall of the first conductive pillar portion 410 may have a first angle IA1 from a horizontal direction. The first angle IA1 may be an acute angle selected from a range of 40 degrees to 80 degrees. The sidewall of the first conductive pillar portion 410 may have a positive slope.

The second conductive pillar portion 420 may be disposed on the first conductive pillar portion 410. The second conductive pillar portion may have a tapered or cylindrical shape. A diameter D2 of the second conductive pillar portion 420 may be equal to or smaller than the first diameter D11 of the upper portion of the first conductive pillar portion 410. A sidewall of the second conductive pillar portion 420 may have a second angle IA2 from the horizontal direction. The second angle IA2 may be an angle selected from a range of 80 degrees to 100 degrees.

The third conductive pillar portion 430 may be disposed on the second conductive pillar portion 420. The third conductive pillar portion 430 may have a second tapered shape. An upper portion of the third conductive pillar portion 430 may have a third diameter D31, and a lower portion of the third conductive pillar portion 430 may have a fourth diameter D32. The fourth diameter D32 may be greater than the third diameter D31. A sidewall of the third conductive pillar portion 430 may have a third angle IA3 from the horizontal direction. The third angle IA3 may be an angle selected from a range of 80 degrees to 100 degrees. The sidewall of the third conductive pillar portion 430 may have a negative slope.

The first conductive pillar portion 410 may have a first length L1, and the third conductive pillar portion 430 may have a third length L3 greater than the first length L1. The second conductive pillar portion 420 may have a second length L2 smaller than the first length L1. The third length L3 may be at least 1.5 times the first length L1. The first conductive pillar portion 410 may have a first aspect ratio, and the third conductive pillar portion 430 may have a second aspect ratio greater than the first aspect ratio. The upper diameter D11 of the first conductive pillar portion 410 opposite to the portion bonded to the conductive structure-connection bonding pads 162 may be greater than the diameter D32 of the lower portion of the third conductive pillar portion 430 adjacent to the first conductive pillar portion 410. An aspect ratio of a conductive pillar portion may be a value of a height divided by a bottom width. For example, the first aspect ratio of the first conductive pillar portion 410 may be a value of the first length L1 divided by the second diameter D12, and the second aspect ratio of the third conductive pillar portion 430 may be a value of the third length L3 divided by the diameter D32.

In example embodiments, the lower redistribution layer 100 may be disposed on the second surface 304 of the sealing member 300 and the first surface 202 of the semiconductor chip 200. The lower redistribution layer 100 may include a plurality of first redistribution wirings 102. The first redistribution wirings 102 may be electrically connected to the conductive bumps 220 on the chip pads 210 and the vertical conductive structures 400. The first redistribution wirings 102 may be disposed on the front surface 202 of the semiconductor chip 200 and the second surface 304 of the sealing member 300 and serve as a front redistribution wiring. Accordingly, the lower redistribution layer 100 may be a front redistribution layer of a fan-out package.

For example, the lower redistribution layer 100 may include first to fourth lower insulating layers 110, 120, 130 and 140 that are sequentially stacked on each other. The first redistribution wirings 102 may include first to third lower redistribution wirings 112, 122 and 132 disposed on the first to fourth lower insulating layers 110, 120, 130 and 140. The first lower redistribution wirings 112 may be electrically connected to the conductive bumps 220 and end portions of the vertical conductive structures 400.

In example embodiments, the upper redistribution layer 500 may be disposed on the first surface 302 of the sealing member 300 and the upper surface 204 of the semiconductor chip 200 and may include second redistribution wirings 502 electrically connected to the vertical conductive structures 400, respectively. The second redistribution wirings 502 may include upper redistribution wirings 512 and 522 stacked in at least two layers. The second redistribution wirings 502 may be disposed on the sealing member 300 and may serve as backside redistribution wirings. Accordingly, the upper redistribution layer 500 may be a backside redistribution layer of the fan-out package.

A first upper insulating layer 510 may be disposed on the first surface 302 of the sealing member 300 and the upper surface 204 of the semiconductor chip 200 and have openings exposing upper surfaces of the conductive structure-connection bonding pads 162. First upper redistribution wirings 512 may be formed on the first upper insulating layer 510, and at least portions of the first upper redistribution wirings 512 may contact the conductive structure-connection bonding pads 162 through the openings.

A second upper insulating layer 520 may be disposed on the first upper insulating layer 510 and have openings exposing the first upper redistribution wirings 512. Second upper redistribution wirings 522 may be formed on the second upper insulating layer 520, and at least portions of the second upper redistribution wirings 522 may contact the first upper redistribution wirings 512 through the openings.

Bonding pads (not illustrated) may be disposed on the second upper redistribution wirings 522, respectively. A third upper insulating layer 530 may be disposed on the second upper insulating layer 520 and expose at least portions of the bonding pads. The third upper insulating layer 530 may serve as a passivation layer.

In example embodiments, external connection members 550 may be disposed on the third lower redistribution wirings 132 that are exposed at an outer surface of the lower redistribution layer 100. The third lower redistribution wirings 132 may serve as package pads to which the external connection members 550 are attached. For example, the external connection member 550 may include or may be a solder ball. The fan-out wafer level package 12 may be mounted on a module substrate (not shown) via the solder balls to form a memory module.

Hereinafter, a method of manufacturing the semiconductor package in FIG. 18 will be described.

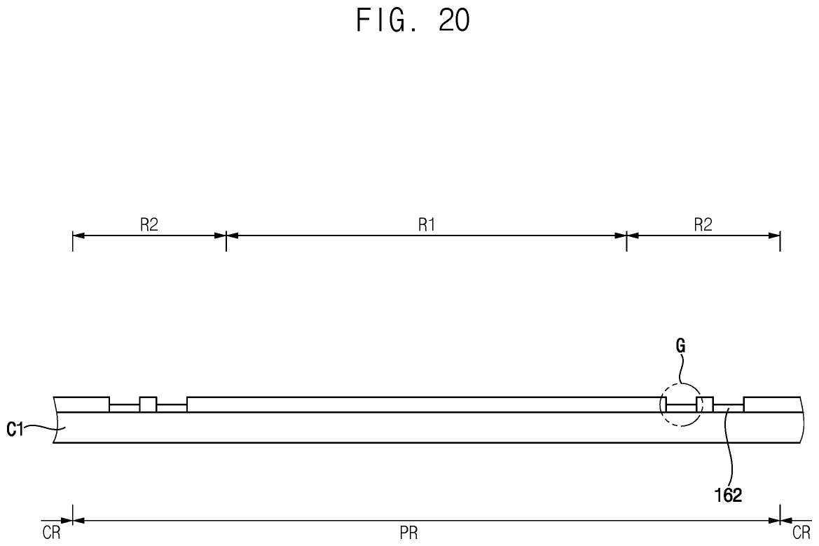

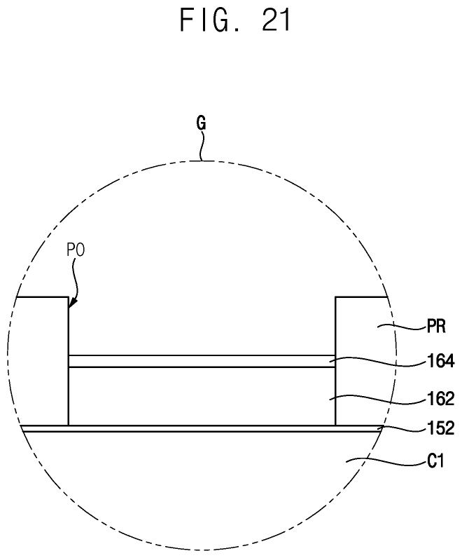

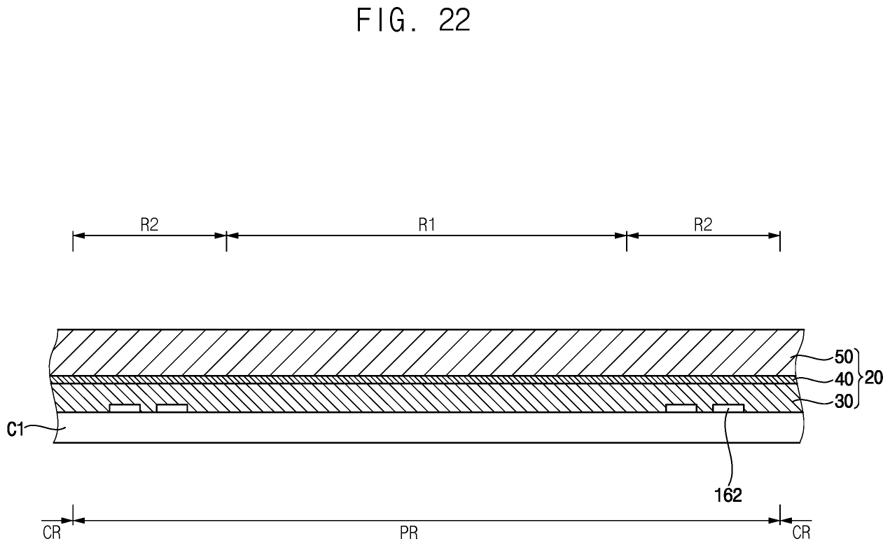

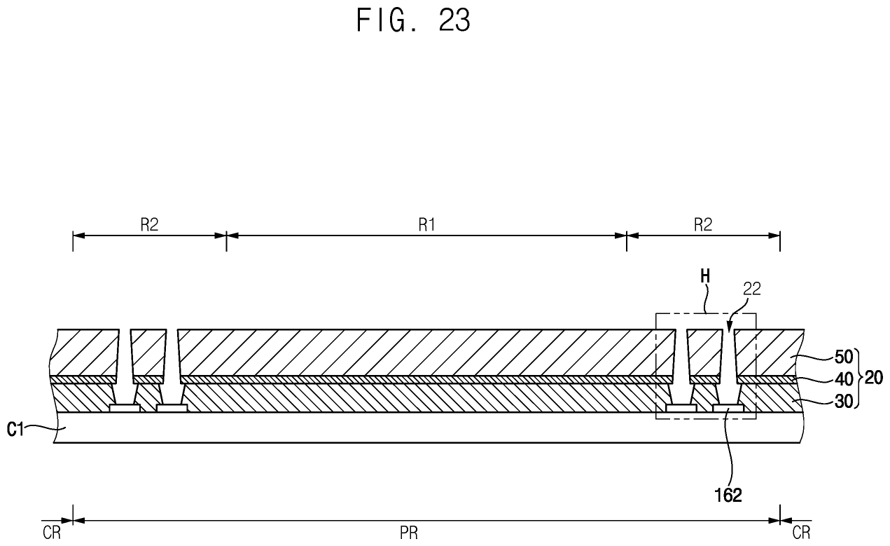

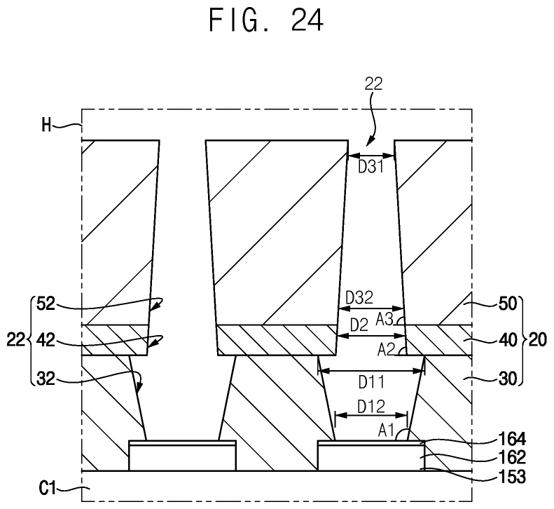

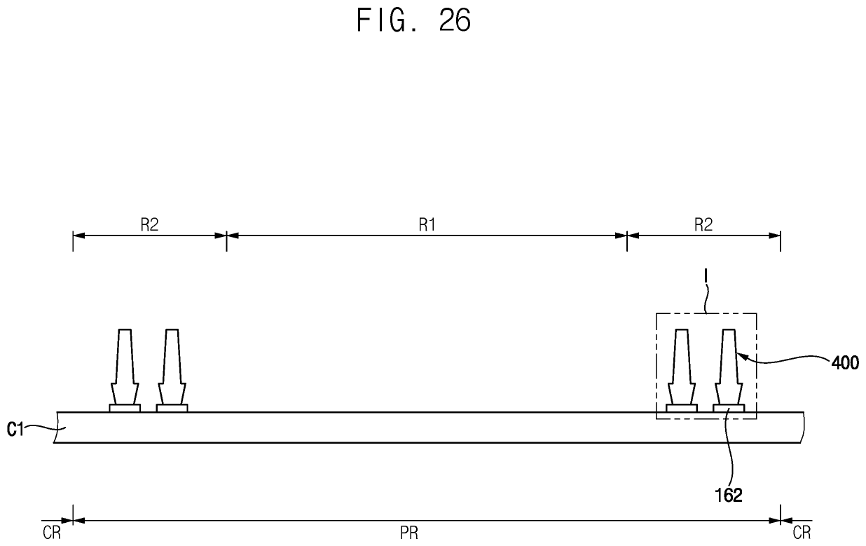

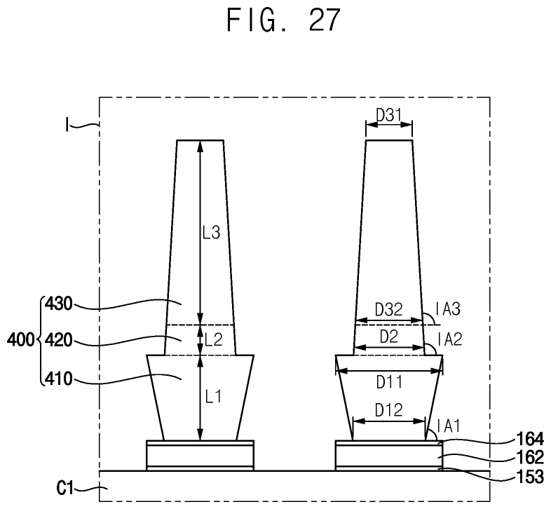

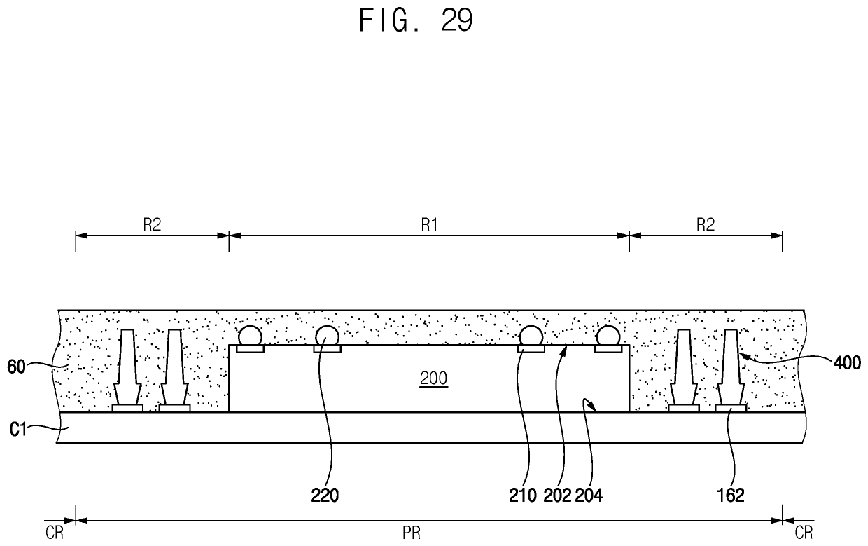

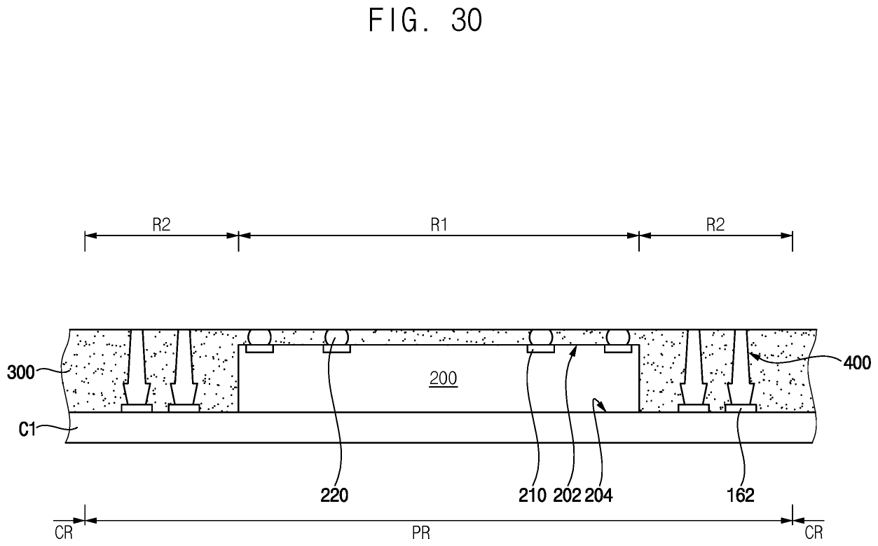

FIGS. 20 to 32 are views illustrating a method of manufacturing a semiconductor package in accordance with example embodiments. FIGS. 20, 22, 23, 25, 26 and 28 to 32 are cross-sectional views illustrating a method of manufacturing a semiconductor package in accordance with example embodiments. FIG. 21 is an enlarged cross-sectional view illustrating portion ‘G’ in FIG. 20. FIG. 24 is an enlarged cross-sectional view illustrating portion ‘H’ in FIG. 23. FIG. 27 is an enlarged cross-sectional view illustrating portion ‘I’ in FIG. 26.

Referring to FIGS. 20 to 27, conductive structure-connection bonding pads 162 and vertical conductive structures 400 may be formed.

First, as illustrated in FIGS. 20 and 21, a first carrier substrate C1 including a package region PR on which a semiconductor chip is mounted and a cutting region CA surrounding the package region PR may be provided.

In example embodiments, the first carrier substrate C1 may be used as a base substrate for stacking the semiconductor chip and forming a molding member covering the semiconductor chip. The first carrier substrate C1 may have a shape corresponding to a wafer on which a semiconductor process is performed. The first carrier substrate C1 may include a first region R1 overlapping the semiconductor chip and a second region R2 surrounding the first region R1. The second region R2 may be a fan-out region outside a region where the semiconductor chip is disposed.

Then, a seed layer 152 may be formed on the first carrier substrate C1, and a photoresist pattern PR having an opening PO exposing a bonding pad region may be formed on the seed layer 152. Then, a plating process may be performed on the seed layer to form the conductive structure-connection bonding pad 162 in the opening. Then, the photoresist pattern PR may be removed from the first carrier substrate C1, and a portion of the seed layer exposed by the conductive structure-connection bonding pad 162 may be removed to form a seed layer pattern. The conductive structure-connection bonding pads 162 may be formed in the second region R2.

As illustrated in FIG. 27, processes the same as or similar to the processes described with reference to FIGS. 5 and 6 may be performed to form a photosensitive insulating material layer 20 formed on the first carrier substrate C1 to cover the conductive structure-connection bonding pads 162. In particular, a first photosensitive insulating layer 30, a light blocking layer 40 and a second photosensitive insulating layer 50 may be sequentially formed on the first carrier substrate C1.

For example, the first photosensitive insulating layer 30 may include or may be formed of a positive photosensitive insulating material. The second photosensitive insulating layer 50 may include or may be formed of a negative photosensitive insulating material.

As illustrated in FIGS. 23 and 24, processes the same as or similar to the processes described with reference to FIGS. 7 to 10 may be performed to form a through hole 22 in the photosensitive insulating material layer 20.

The through hole 22 may be formed in the first photosensitive insulating layer 30, the light blocking layer 40 and the second photosensitive insulating layer 50, and may have first to third openings 32, 42 and 52 communicating with each other.

The third opening 52 of the second photosensitive insulating layer 50 may have a second tapered shape. An upper portion of the third opening 52 may have a third diameter D31, and a lower portion of the third opening 52 may have a fourth diameter D32. The fourth diameter D32 may be greater than the third diameter D31. A sidewall of the third opening 52 may have a third angle A3 from a horizontal direction. The third angle may be an angle selected from a range of 80 degrees to 100 degrees. The sidewall of the third opening 52 may have a negative slope by a negative type photoresist.

The second opening 42 of the light blocking layer 40 may have a tapered or cylindrical shape similar to the third opening 52. A diameter D2 of the second openings 42 may be equal to or greater than the second diameter D32 of the lower portion of the third opening 52. A sidewall of the second opening 42 may have a second angle A2 from the horizontal direction. The second angle A2 may be an angle selected from a range of 80 degrees to 100 degrees.

The first opening 32 of the first photosensitive insulating layer 30 may have a tapered shape. An upper portion of the first opening 32 may have a first diameter D11, and a lower portion of the first opening 32 may have a second diameter D12. The second diameter D12 may be greater than the first diameter D11. A sidewall of the first opening 32 may have a first angle A1 from the horizontal direction. The first angle A1 may be an obtuse angle selected from a range of 100 degrees to 140 degrees. The sidewall of the first opening 32 may have a positive slope by a positive type photoresist.

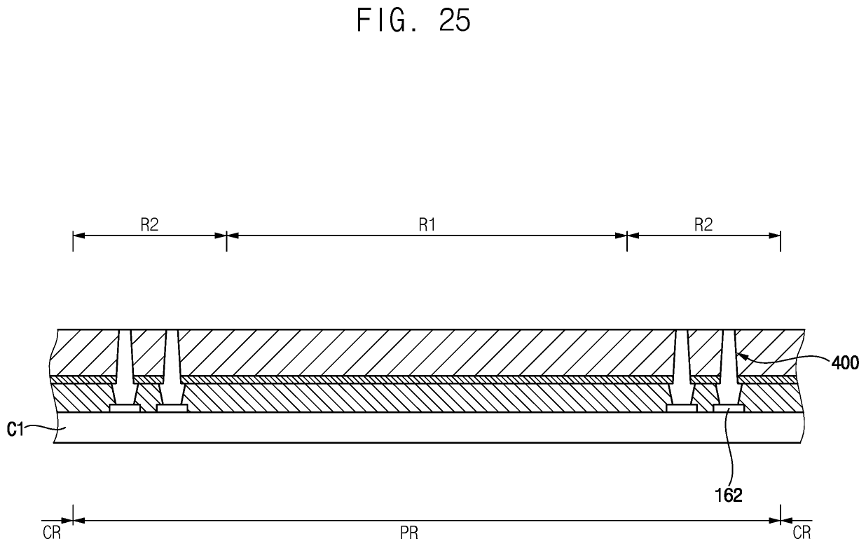

As illustrated in FIGS. 25 to 27, processes the same as or similar to the processes described with reference to FIGS. 11 to 13 may be performed to fill up a conductive material in the through hole 22 of the photosensitive insulating material layer 20 by an electroplating process to form the vertical conductive structures 400.

The vertical conductive structure 400 may extend upwardly from the conductive structure-connection bonding pad 162. For example, the vertical conductive structure 400 may include or may be formed of Cu. A lower portion of the vertical conductive structure 400 may be bonded to a plating pattern 164 on the conductive structure-connection bonding pad 162.

The vertical conductive structure 400 may include first to third conductive pillar portions 410, 420 and 430 that are sequentially stacked on the conductive structure-connection bonding pad 162. The first conductive pillar portion 410 may have a first tapered shape corresponding to the shape of the first opening 32. A sidewall of the first conductive pillar portion 410 may have a positive slope. The second conductive pillar portion 420 may be disposed on the first conductive pillar portion 410. The second conductive pillar portion 420 may have a tapered shape or a cylindrical shape corresponding to the shape of the second opening 42. The third conductive pillar portion 430 may be disposed on the second conductive pillar portion 420. The third conductive pillar portion 430 may have a second tapered shape corresponding to the shape of the third opening 52. A sidewall of the third conductive pillar portion 430 may have a negative slope.

The first conductive pillar portion 410 may have a first length L1, and the third conductive pillar portion 430 may have a third length L3 greater than the first length L1. The third length L3 may be at least 1.5 times the first length L1. The first conductive pillar portion 410 may have a first aspect ratio, and the third conductive pillar portion 430 may have a second aspect ratio greater than the first aspect ratio. The upper diameter D11 of the first conductive pillar portion 410 opposite to the portion bonded to the conductive structure-connection bonding pads 162 may be greater than the diameter D32 of the lower portion of the third conductive pillar portion 430 adjacent to the first conductive pillar portion 410.

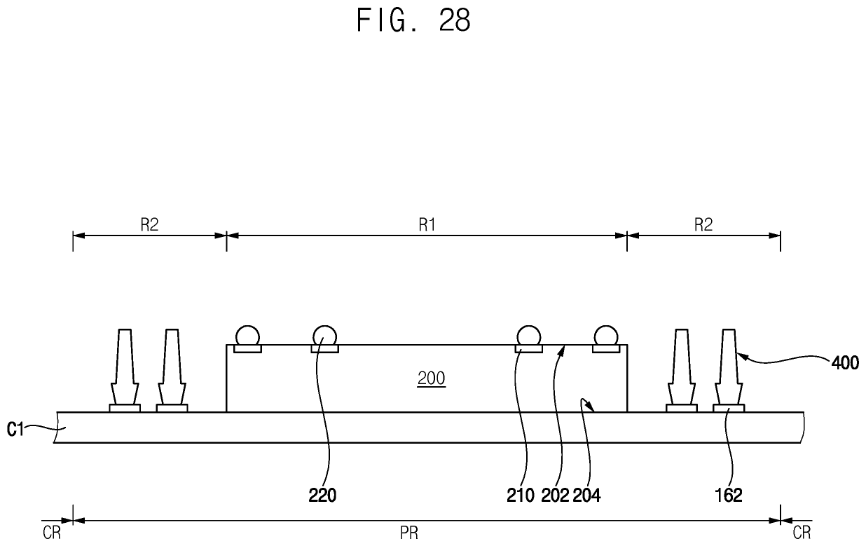

Referring to FIG. 28, at least one semiconductor chip 200 may be disposed on the first carrier substrate C1.

In example embodiments, conductive bumps 220 may be formed on chip pads 210 of the semiconductor chip 200, and a backside surface 204 of the semiconductor chip 200 may face (i.e., may be adjacent to) the first carrier substrate C1. The backside surface 204 may be opposite to a front surface 202 of the semiconductor chip 200. The front surface 202 may correspond to an active surface at which a plurality of transistors are formed. The semiconductor chip 200 may be disposed in a first region R1 that is a fan-in region of the first carrier substrate C1. The plurality of vertical conductive structures 400 may be disposed in a second region R2 around the semiconductor chip 200.

The conductive bump 220 may include a pillar bump formed on the chip pad 210 of the semiconductor chip 200 and a solder bump formed on the pillar bump. Alternatively, the conductive bumps 220 may include a solder bump formed on the chip pad 210 of the semiconductor chip 200.

Referring to FIGS. 28 to 30, a sealing material 60 may be formed on the first carrier substrate C1 to cover the semiconductor chip 200 and the plurality of vertical conductive structures 400, and an upper portion of the sealing material 60 may be partially removed to form a sealing member 300 and to expose upper surfaces of the plurality of vertical conductive structures 400 and upper surfaces of the conductive bumps 220 that are disposed on the front surface 202 of the semiconductor chip 200.

The sealing material 60 may be formed to cover the front surface 202 of the semiconductor chip 200 and the upper surfaces of the plurality of the vertical conductive structures 400. For example, the sealing material 60 may include or may be formed of an epoxy mold compound (EMC).

An upper portion of the sealing material 60 may be partially removed by a grinding process. As the upper portion of the sealing material 60 is removed, the conductive bumps 220 on the front surface 202 of the semiconductor chip 200 and the plurality of vertical conductive structures 400 may be exposed from a second surface 304 of the sealing member 300. The sealing member 300 may include a first sealing portion covering the front surface 202 of the semiconductor chip 200 and a second sealing portion covering a side surface of the semiconductor chip 200. The upper surfaces of the conductive bumps 220 on the front surface 202 of the semiconductor chip 200 may be exposed by the first sealing portion of the sealing member 300.

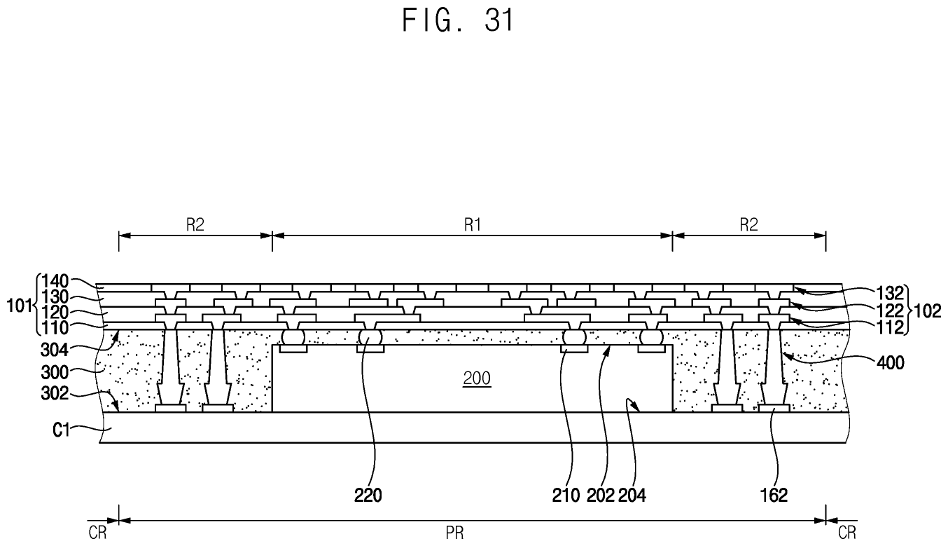

Referring to FIG. 31, a lower redistribution layer 100 having first redistribution wirings 102 may be formed on the second surface 304 of the sealing member 300 and the front surface 202 of the semiconductor chip 200.

In example embodiments, after forming a first lower insulating layer 110 on the second surface 304 of the sealing member 300 and the front surface of the semiconductor chip 200, the first lower insulating layer 110 may be patterned to form openings that expose the vertical conductive structures and the conductive bumps 220. Some openings of the patterned first lower insulating layer 110 may expose the vertical conductive structures 400, and the others may expose the conductive bumps 220.

A seed layer may be formed on the vertical conductive structures 400 and the conductive bumps 220 and in the openings of the first lower insulating layer 110, the seed layer may be patterned and an electroplating process may be performed to form first lower redistribution wirings 112. Accordingly, at least portions of the first lower redistribution wirings 112 may contact end portions of the vertical conductive structures 400 and the conductive bumps 220 through the openings.

Similarly, after forming a second lower insulating layer 120 on the first lower insulating layer 110, the second lower insulating layer 120 may be patterned to form openings exposing the first lower redistribution wirings 112. Then, second lower redistribution wirings 122 may be formed on the second lower insulating layer 120 to contact the first lower redistribution wirings 112 through openings of the second lower insulating layer 120.

Then, after forming a third lower insulating layer 130 on the second lower insulating layer 120, the third lower insulating layer 130 may be patterned to form openings exposing the second lower redistribution wirings 122. Then third lower redistribution wirings 132 may be formed on the third lower insulating layer 130 to contact the second lower redistribution wirings 122 through openings of the third lower insulating layer 130.

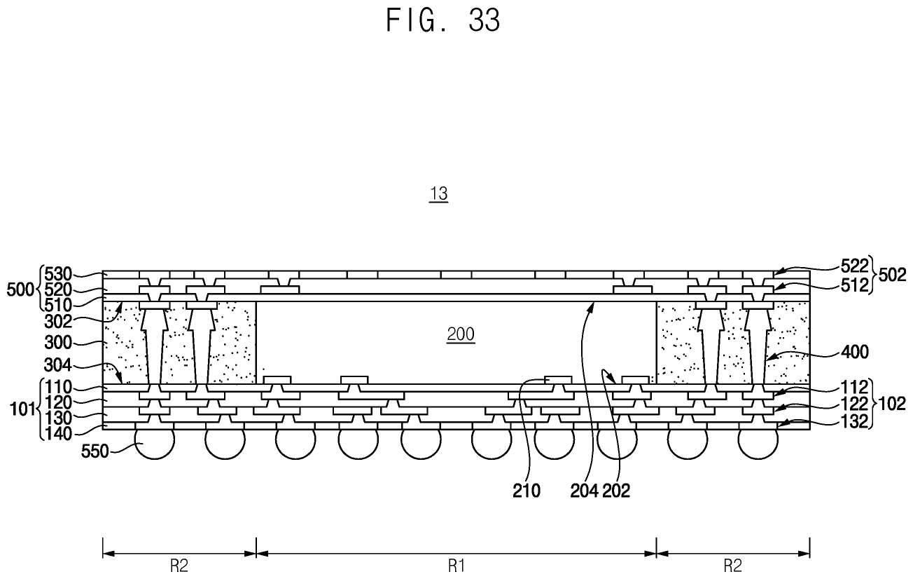

Then, package pads may be formed on the third lower redistribution wirings 132 respectively, and fourth lower insulating layer 140 may be formed on the third lower insulating layer 130 to expose at least a portion of the package pad of the third lower redistribution wiring 132. In some embodiments, the third lower redistribution wirings 132 may serve as package pads to which external connection members 550 of FIG. 33 are attached.

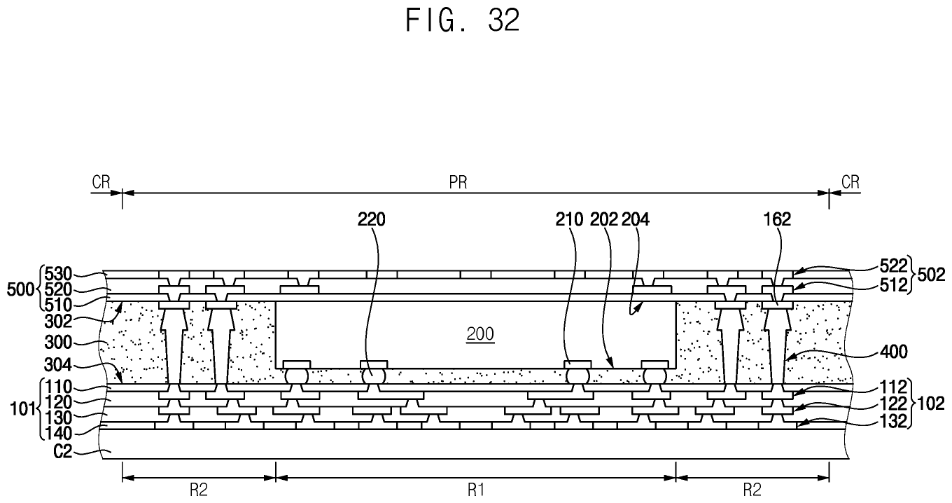

Referring to FIG. 32, after removing the first carrier substrate C1, the structure in FIG. 31 may be turned over, and processes the same as or similar to the processes as described with reference to FIG. 16 may be performed to form an upper redistribution layer 500 having second redistribution wirings 502 that are electrically connected to the vertical conductive structures 400 on the first surface 302 of the sealing member 300. A second carrier substrate C2 may be attached to the lower redistribution layer 100 before or after the removal of the first carrier substrate C1.

In example embodiments, after forming a first upper insulating layer 510 on the first surface 302 of the sealing member 300, the first upper insulating layer 510 may be patterned to form openings exposing conductive-structure connection-bonding pads 162. The openings of the patterned first upper insulating layer 510 may expose the conductive structure-connection bonding pads 162.

Then, after forming a seed layer in the openings and on portions of the exposed conductive structure-connection bonding pads 162, the seed layer may be patterned, and an electroplating process may be performed to form first upper redistribution wirings 512. Accordingly, at least portions of the first upper redistribution wirings 512 may be electrically connected to the vertical conductive structures 400 through the openings.

Then, after forming a second upper insulating layer 520 on the first upper insulating layer 510, the second upper insulating layer 520 may be patterned to form openings exposing the first upper redistribution wirings 512. Then, second upper redistribution wirings 522 may be formed on the second upper insulating layer 520 to contact the first upper redistribution wirings 512 through openings of the second upper insulating layer 520.

Accordingly, the second redistribution wirings 502 may include the first upper redistribution wiring 512 and the second upper redistribution wiring 522 stacked in at least two layers. In this case, the second upper redistribution wiring 522 may be the uppermost redistribution wiring among the second redistribution wirings.

Then, upper bonding pads (not shown) may be formed on the second upper redistribution wirings 522 as the uppermost redistribution wirings, and a third upper insulating layer 530 may be formed on the second upper insulating layer 520 to expose at least portions of the upper bonding pads on the second upper redistribution wirings 522. The third upper insulating layer 530 may serve as a passivation layer.

Then, the second carrier substrate C2 may be removed, and external connection members 550 (see FIG. 18) may be formed on package pads on an outer surface, that is, a lower surface of the lower redistribution layer 100.

Then, the lower redistribution layer 100 may be separated individually by a sawing process to complete the fan-out wafer level package 12 of FIG. 18. The fan-out wafer level package 12 may include the sealing member 300, the lower redistribution layer 100 formed on a lower surface 304 of the sealing member 300 and the upper redistribution layer 500 formed on the upper surface 302 of the sealing member 300.

FIG. 33 is a cross-sectional view illustrating a semiconductor package in accordance with example embodiments. The semiconductor package is substantially the same as the semiconductor package described with reference to FIG. 18 except for a connection relationship between a semiconductor chip and a lower redistribution layer. Accordingly, same reference numerals may be used to refer to the same or like elements and any further repetitive explanation concerning the above elements will be omitted.

Referring to FIG. 33, a fan-out wafer level package 13 may include a lower redistribution layer 100, a semiconductor chip 200 disposed on the lower redistribution layer 100, a sealing member 300 covering at least one side surface of the semiconductor chip 200 on the lower redistribution layer 100, an upper redistribution layer 500 disposed on the sealing member 300, and a plurality of vertical conductive structures 400 penetrating the sealing member 300 to electrically connect the lower redistribution layer 100 and the upper redistribution layer 500 with each other. Additionally, the fan-out wafer level package 12 may further include external connection members 550 disposed on an outer surface of the lower redistribution layer 100.

In example embodiments, the semiconductor chip 200 may have a plurality of chip pads 210 on a first surface 202, that is, an active surface of the semiconductor chip 200. The semiconductor chip 200 may be accommodated in the sealing member 300 such that the first surface 202 on which the chip pads 210 are formed faces the lower redistribution layer 100. The sealing member 300 may cover an outside surface of the semiconductor chip 200. The first surface 202 of the semiconductor chip 200 may be exposed from a second surface 304 of the sealing member 300, and a second surface 204 opposite to the first surface 202 of the semiconductor chip 200 may be exposed from a first surface 302 of the sealing member 300.

In example embodiments, the lower redistribution layer 100 may be disposed on the second surface 304 of the sealing member 300 and the first surface 202 of the semiconductor chip 200. The lower redistribution layer 100 may include a plurality of first redistribution wirings 102. The first redistribution wirings 102 may be electrically connected to the chip pads 210 of the semiconductor chip 200 and the vertical conductive structures 400. The first redistribution wirings 102 may be disposed on the front surface 202 of the semiconductor chip 200 and the second surface 304 of the sealing member 300 and may serve as a front redistribution wiring. Thus, the lower redistribution layer 100 may be a front redistribution layer of a fan-out package.

Hereinafter, a method of manufacturing the semiconductor package of FIG. 33 will be described.

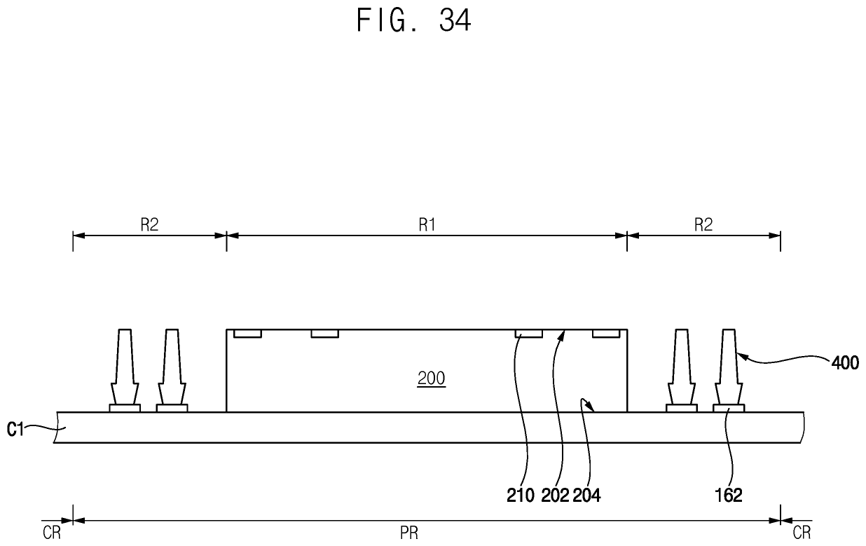

FIGS. 34 to 38 are views illustrating a method of manufacturing a semiconductor package in accordance with example embodiments.

Referring to FIG. 34, first, processes equal to or similar to those described with reference to FIGS. 20 to 27 may be performed to form conductive-structure-connection bonding pads 162 and vertical conductive structures 400.

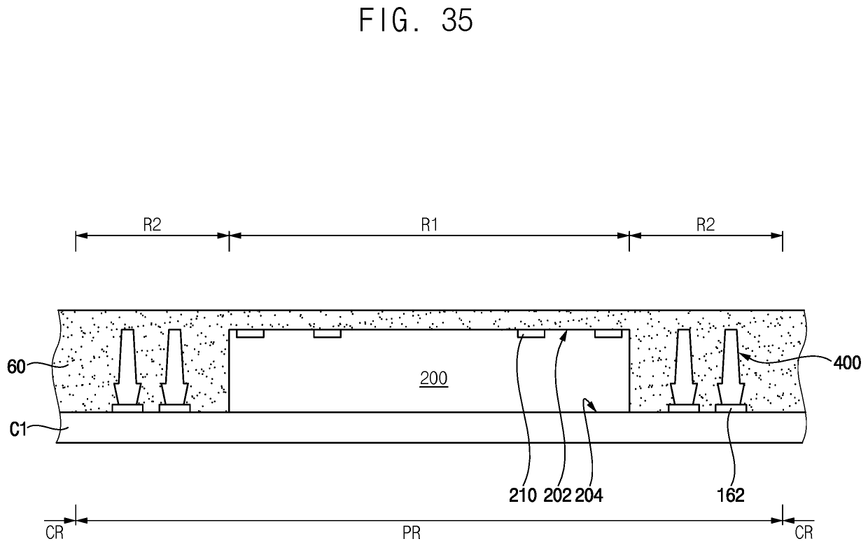

Referring to FIG. 35, at least one of a semiconductor chip 200 may be disposed on a first carrier substrate C1, and sealing material 60 covering the semiconductor chip 200 and a plurality of the vertical conductive structures 400 may be formed on the first carrier substrate C1.

In example embodiments, the semiconductor chip 200 may be disposed on a fan-in region of the first carrier substrate C1. The vertical conductive structures 400 may be disposed around the semiconductor chip 200. A backside surface 204 of the semiconductor chip 200 may face (i.e., may be adjacent to) the first carrier substrate C1. The backside surface 204 may be opposite to a front surface 202 that corresponds to an active surface of the semiconductor chip 200 at which a plurality of transistors are formed.

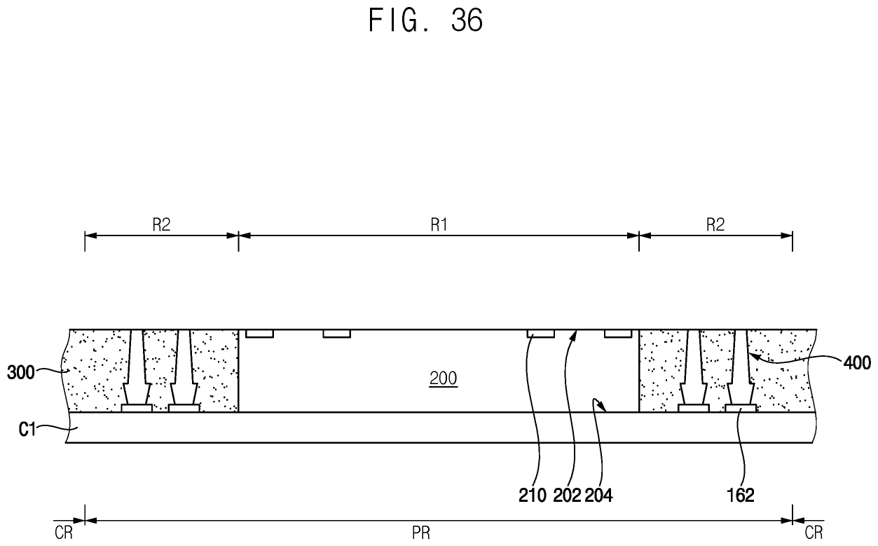

Referring to FIG. 36, an upper portion of the sealing material 60 may be removed to form a sealing member 300 that exposes the front surface 202 of the semiconductor chip 200 and end portions of the plurality of vertical conductive structures 400.

The upper portion of the sealing material 60 may be partially removed by a grinding process. As the upper portion of the sealing material 60 is removed, end portions of the chip pads 210 and the plurality of vertical conductive structures 400 on the front surface 202 of the semiconductor chip 200 may be exposed from a second surface 304 of the sealing member 300. The sealing member 300 may cover a side surface of the semiconductor chip 200.

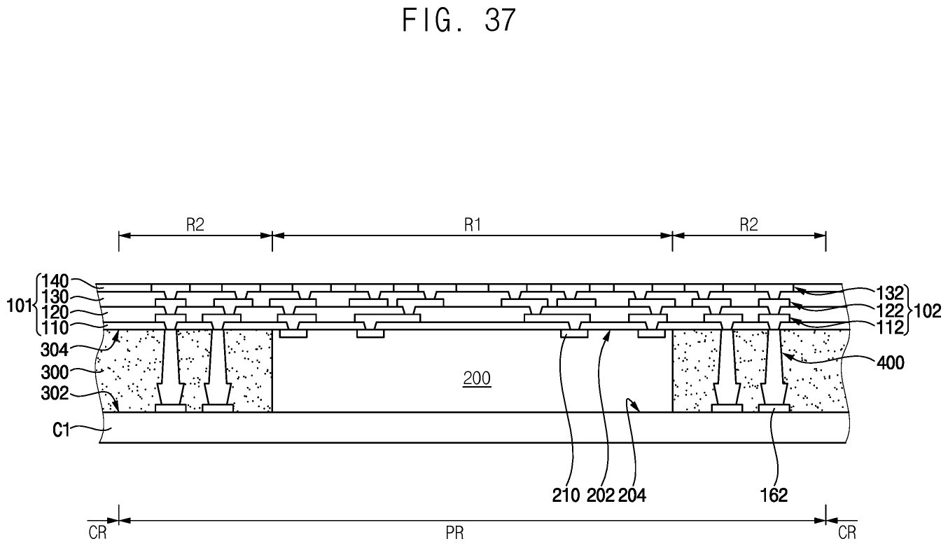

Referring to FIG. 37, processes equal to or similar to those described with reference to FIG. 31 may be performed to form the lower redistribution layer 100 having first redistribution wirings 102 on the second surface 304 of the sealing member 300 and the front surface 202 of the semiconductor chip 200.

In example embodiments, after forming a first lower insulating layer 110 on the second surface 304 of the sealing member 300, the first lower insulating layer 110 may be patterned to form openings that expose the vertical conductive structures 400 and the chip pads 210 of the semiconductor chip 200, respectively. Some openings of the patterned first lower insulating layer 110 may expose the vertical conductive structures 400, and the other openings may expose the chip pads 210.

After forming a seed layer on the vertical conductive structures 400, the seed layer may be patterned and an electroplating process may be performed to form first lower redistribution wirings 112 on the chip pads and in the openings. Thus, at least portions of the first lower redistribution wirings 112 may be directly connected to the vertical conductive structures 400 and the chip pads 210 through the openings.

Then, after forming a third lower insulating layer 130 on a second lower insulating layer 120, the third lower insulating layer 130 may be patterned to form openings that expose second lower redistribution wirings 122. Then, third lower redistribution wirings 132 may be formed on the third lower insulating layer 130 to be directly connected to the second lower redistribution wirings 122 through the openings, respectively.

Then, package pads may be formed in the third lower redistribution wirings 132, respectively, and fourth lower insulating layer 140 may be formed on the third lower redistribution wirings 132 to expose at least portions of the package pads on the third lower redistribution wirings 132. The fourth lower insulating layer 140 may serve as a passivation layer.

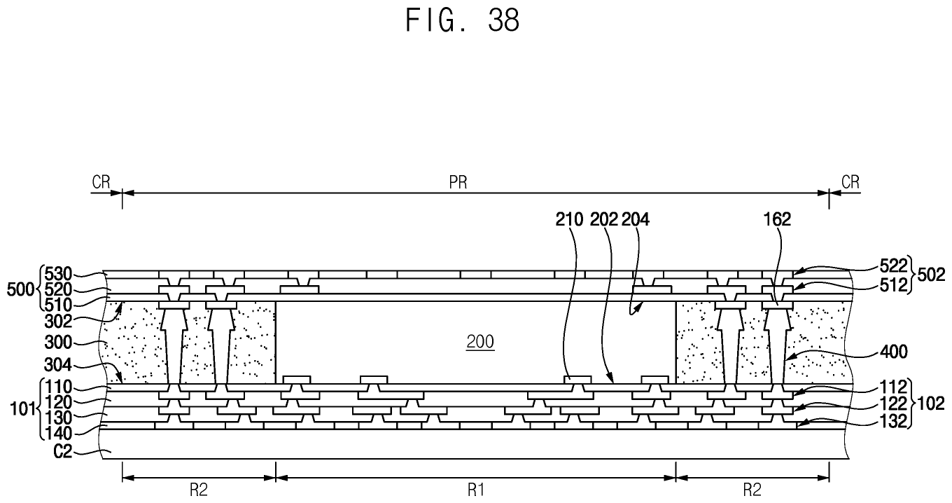

Referring to FIG. 38, same or similar processes as those described with reference to FIG. 32 may be performed to form an upper redistribution layer 500 having second redistribution wirings 502 electrically connected to the vertical conductive structures 400 that is on the upper surface 302 of the sealing member 300, and external connection members 550 may be formed on an outside surface of the lower redistribution layer 100 to be electrically connected to the first redistribution wirings 102, respectively, and the fan-out wafer level package 13 in FIG. 33 may be completed.

The above-described semiconductor package may include a semiconductor device such as a logic device and a memory device. The semiconductor package may include a logic device such as a central processing unit (CPU, MPU), an application processor (AP), a volatile memory device such as an SRAM device and a DRAM device, and a nonvolatile memory device such as a flash memory device, a PRAM device, an MRAM device, and an RRAM device.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package comprising:
a lower redistribution layer having a first region and a second region surrounding the first region, wherein the lower redistribution layer includes a plurality of first redistribution wirings;
a semiconductor chip disposed on the first region of the lower redistribution layer and electrically connected to the plurality of first redistribution wirings;
a sealing member disposed on the lower redistribution layer and covering the semiconductor chip;
a plurality of vertical conductive structures disposed on the second region of the lower redistribution layer and penetrating the sealing member,
wherein the plurality of vertical conductive structures are electrically connected to the plurality of first redistribution wirings;
an upper redistribution layer disposed on the sealing member,
wherein the upper redistribution layer includes a plurality of second redistribution wirings that are electrically connected to the plurality of vertical conductive structures; and
a plurality of bonding pads,
wherein the plurality of vertical conductive structures are connected to the plurality of bonding pads and extend from the plurality of bonding pads in a vertical direction that is perpendicular to an upper surface of the lower redistribution layer,
wherein each of the plurality of vertical conductive structures includes a first conductive pillar portion, a second conductive pillar portion, and a third conductive pillar portion that are sequentially stacked on a corresponding bonding pad of the bonding pads,
wherein the first conductive pillar portion has a first length in the vertical direction and the third conductive pillar portion has a third length in the vertical direction greater than the first length, and
wherein a diameter of an upper surface of the first conductive pillar portion that is opposite to a lower surface thereof bonded to the corresponding bonding pad is greater than a diameter of a lower surface of the third conductive pillar portion that is adjacent to the first conductive pillar portion.

2. The semiconductor package of claim 1,
wherein the plurality of bonding pads are provided on an upper surface of the lower redistribution layer, and
wherein the first conductive pillar portion has a first tapered shape, the second conductive pillar portion has a second tapered shape or a cylindrical shape, and the third conductive pillar portion has a third tapered shape.

3. The semiconductor package of claim 1,
wherein the plurality of bonding pads are provided on a lower surface of the upper redistribution layer.

4. The semiconductor package of claim 1,
wherein a sidewall of the first conductive pillar portion has a first angle from a horizontal direction that is parallel to an upper surface of the lower redistribution layer, and
wherein the first angle is an acute angle selected from a range of 40 degrees to 80 degrees.

5. The semiconductor package of claim 1,
wherein a sidewall of the third conductive pillar portion has a third angle from a horizontal direction that is parallel to the upper surface of the lower redistribution layer, and
wherein the third angle is an angle selected from a range of 80 degrees to 100 degrees.

6. The semiconductor package of claim 1,
wherein the third length of the third conductive pillar portion is at least 1.5 times of the first length of the first conductive pillar portion.

7. The semiconductor package of claim 1,
wherein the first conductive pillar portion has a first aspect ratio and the third conductive pillar portion has a second aspect ratio greater than the first aspect ratio.

8. The semiconductor package of claim 1, further comprising:
a plurality of plating patterns disposed on the plurality of bonding pads, respectively.

9. The semiconductor package of claim 8,
wherein the first conductive pillar portion of each of the plurality of vertical conductive structures is connected to a corresponding one of the plurality of plating patterns.

10. The semiconductor package of claim 1, further comprising:
a second package disposed on the upper redistribution layer,
wherein the second package includes a package substrate and at least one second semiconductor chip stacked on the package substrate.

11. A semiconductor package comprising:
a lower redistribution layer having a plurality of first redistribution wirings;
a semiconductor chip disposed on the lower redistribution layer,
wherein the semiconductor chip includes a plurality of chip pads at a first surface of the semiconductor chip, and
wherein the first surface of the semiconductor chip is adjacent to the lower redistribution layer;
a sealing member disposed on the lower redistribution layer and covering the semiconductor chip;
a plurality of vertical conductive structures penetrating the sealing member and electrically connected to the plurality of first redistribution wirings;
an upper redistribution layer disposed on the sealing member and having a plurality of second redistribution wirings that are electrically connected to the plurality of vertical conductive structures; and
a plurality of bonding pads respectively connected to one end portions of the plurality of vertical conductive structures,
wherein each of the plurality of vertical conductive structures includes a first conductive pillar portion, a second conductive pillar portion, and a third conductive pillar portion that are sequentially stacked on a corresponding bonding pad of the plurality of bonding pads,
wherein the first conductive pillar portion has a first length, the second conductive pillar portion has a second length less than the first length, and the third conductive pillar portion has a third length greater than the first length, and
wherein the first conductive pillar portion has a first tapered shape and the third conductive pillar portion has a third tapered shape different from the first tapered shape.

12. The semiconductor package of claim 11,
wherein the first conductive pillar portion has an increasing diameter in a vertical direction, and the third conductive pillar has a decreasing diameter in the vertical direction, and
wherein the second conductive pillar portion is disposed between the first conductive pillar portion and the third conductive pillar portion and has a second tapered shape or a cylindrical shape.

13. The semiconductor package of claim 11,
wherein a sidewall of the first conductive pillar portion has a first angle from a horizontal direction, and the first angle is an acute angle selected from a range of 40 degrees to 80 degrees.

14. The semiconductor package of claim 11,
wherein a sidewall of the third conductive pillar portion has a third angle from a horizontal direction, and the third angle is an angle selected from a range of 80 degrees to 100 degrees.

15. The semiconductor package of claim 11,
wherein the third length of the third conductive pillar portion is at least 1.5 times of the first length of the first conductive pillar portion.

16. The semiconductor package of claim 11,
wherein the first conductive pillar portion has a first aspect ratio and the third conductive pillar portion has a second aspect ratio greater than the first aspect ratio.

17. The semiconductor package of claim 11,
wherein a diameter of an upper surface of the first conductive pillar portion that is opposite to a lower surface thereof connected to the corresponding bonding pad is greater than a diameter of a lower surface of the third conductive pillar portion that is adjacent to the first conductive pillar portion.

18. The semiconductor package of claim 11, further comprising:
a plurality of plating patterns respectively disposed on the plurality of bonding pads.

19. The semiconductor package of claim 11,
wherein the semiconductor chip is mounted on the lower redistribution layer via a plurality of conductive bumps.

20. A semiconductor package comprising:
a lower redistribution layer having a first region and a second region surrounding the first region, wherein the lower redistribution layer includes a plurality of first redistribution wirings;
a semiconductor chip disposed on the first region of the lower redistribution layer,
wherein the semiconductor chip includes a plurality of chip pads at a first surface of the semiconductor chip, and
wherein the first surface of the semiconductor chip is adjacent to the lower redistribution layer;
a sealing member disposed on the lower redistribution layer and covering the semiconductor chip;
a plurality of vertical conductive structures penetrating the sealing member,
wherein the plurality of vertical conductive structures are disposed on the second region of the lower redistribution layer and are electrically connected to the plurality of first redistribution wirings;
an upper redistribution layer disposed on the sealing member and having a plurality of second redistribution wirings electrically connected to the plurality of vertical conductive structures; and
a plurality of bonding pads respectively bonded to one end portions of the plurality of vertical conductive structures,
wherein each of the plurality of vertical conductive structures includes a first conductive pillar portion, a second conductive pillar portion and a third conductive pillar portion that are sequentially stacked on a corresponding bonding of the plurality of bonding pads,
wherein the first conductive pillar portion has a first aspect ratio and the third conductive pillar portion has a second aspect ratio greater than the first aspect ratio, and
wherein a diameter of an upper surface of the first conductive pillar portion that is opposite to a lower surface thereof connected to the bonding pad is greater than a diameter of a lower surface of the third conductive pillar portion that is adjacent to the first conductive pillar portion.
